(19) United States
(12) Patent Application Publication
(10) Pub. No.: US 2025/0372393 A1
(43) Pub. Date: Dec. 4, 2025

(54) SEMICONDUCTOR DEVICES AND METHODS OF MAKING SEMICONDUCTOR DEVICES

(71) Applicant: Taiwan Semiconductor Manufacturing Company, Ltd., Hsinchu (TW)

(72) Inventor: Tzu-Ging LIN, Hsinchu (TW)

(73) Assignee: Taiwan Semiconductor Manufacturing Company, Ltd., Hsinchu (TW)

(21) Appl. No.: 18/678,705

(22) Filed: May 30, 2024

(51) Int. Cl. H01L 21/311; H01L 21/762; H01L 29/423; H01L 29/66; H01L 29/78

(52) U.S. Cl. CPC H01L 21/31144; H01L 21/76224; H10D 30/024; H10D 30/6215; H10D 30/6735; H01L 21/31116

(57) ABSTRACT

A method of manufacturing a semiconductor device includes extending an opening through a gate structure, a fin or sheet stack, a shallow trench isolation region, and into a substrate to a depth below the shallow trench isolation region and source/drain structures. A semiconductor device includes a substrate, a shallow trench isolation region over the substrate, a fin or sheet stack over the substrate, a gate structure disposed over the substrate and the shallow trench isolation region, source/drain structures, and an opening containing a dielectric material extending into the substrate to a depth below the shallow trench isolation region and the source/drain structures.

### BACKGROUND

The semiconductor device manufacturing industry has experienced exponential growth. Over time, technological advances in materials, design, and fabrication have produced semiconductor devices with progressively smaller and more complex circuits. During the evolution of semiconductor devices, the number of interconnected devices per chip area has generally increased while the dimensions of circuit components have generally decreased. This scaling-down of semiconductor device architecture generally increases the complexity of processing and manufacturing semiconductor devices.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A and 1B show cross-sections of an opening formed during the manufacture of a semiconductor device according to embodiments of the disclosure.

FIG. 2 shows different openings formed in substrates of semiconductor devices according to embodiments of the disclosure.

FIGS. 3A and 3C show plan views of openings formed in structures of semiconductor devices according to embodiments of the disclosure.

FIGS. 3B and 3D show cross-sections of openings formed in structures of semiconductor devices according to embodiments of the disclosure.

FIGS. 4A, 4B, 4C, and 4D show cross-sections of structures of semiconductor devices according to embodiments of the disclosure.

FIGS. 5A, 5B, 5C, and 5D show cross-sections of structures of semiconductor devices according to embodiments of the disclosure.

FIGS. 6A and 6B show cross-sections of a structure of a semiconductor device according to an embodiment of the disclosure.

FIGS. 7A and 7B show cross-sections of a structure of a semiconductor device according to an embodiment of the disclosure.

FIG. 8 is a flow chart of a method of manufacturing a semiconductor device according to an embodiment of the disclosure.

FIG. 9 is a flow chart of method of manufacturing a semiconductor device according to an embodiment of the disclosure.

FIGS. 10A, 10B, 11A, 11B, 12A, 12B, 13A, 13B, 14A, 14B, 15A, 15B, 16A, 16B, 17A, 17B show cross-section views of sequential process stages of a method of manufacturing a semiconductor device according to embodiments of the disclosure.

FIGS. 18A, 18B, 19A, 19B, 20A, 20B, 21A, 21B, 22A, 22B, 23A, 23B, 24A, 24B, 25A, and 25B show cross-sections views of sequential process stages of a method of manufacturing a semiconductor device according to embodiments of the disclosure.

FIGS. 26A, 26B, 26C, 27A, 27B, 27C, 28A, 28B, 28C, 29A, 29B, 29C, 30A, 30B, 30C, 31B, 31C, 32B, and 32C show cross-section views of sequential process stages of a method of manufacturing a semiconductor device according to embodiments of the disclosure.

FIGS. 33A, 33B, 34A, 34B, 35A, 35B, 36A, 36B, 37A, 37B, 38A, 38B, 39A, and 39B show cross-section views of sequential process stages of a method of manufacturing a semiconductor device according to embodiments of the disclosure.

FIGS. 40A, 40B, 41A, 41B, 42A, 42B, 43A, 43B, 44A, 44B, 45A, and 45B show cross-sections views of sequential process stages of a method of manufacturing a semiconductor device according to embodiments of the disclosure.

FIGS. 46A, 46B, 47A, 47B, 48A, 48B, 49A, 49B, 50A, 50B, 51A, 51B, 52A, and 52B show cross-section views of sequential process stages of a method of manufacturing a semiconductor device according to embodiments of the disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper,” “top,” “bottom,” “middle,” and the like, may be used herein for ease of description to describe one element or feature's relationship to another element(s) or feature(s) as illustrated in the figures, and do not preclude additional structures above or below or between the stated feature. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

Further, in the following fabrication process, there may be one or more additional operations in between the described operations, and the order of operations may be changed. In the present disclosure, a phrase “one of A, B and C” means “A, B and/or C” (A, B, C, A and B, A and C, B and C, or A, B and C), and does not mean one element from A, one element from B and one element from C, unless otherwise described. In the entire disclosure, a source and a drain are interchangeably used, and a source/drain refers to one of or both of the source and the drain. In the following embodiments, materials, configurations, dimensions, processes and/or operations as described with respect to one embodiment (e.g., one or more figures) may be employed in the other embodiments, and detailed description thereof may be omitted. Source/drain structure(s) may refer to a source or a drain, individually or collectively dependent upon the context.

The present disclosure generally relates to semiconductor devices and methods of making semiconductor devices including one or more field effect transistors (FETs). Examples of FETs encompassed by the present disclosure include planar FETs, fin FETs, sheet FETs such as nanosheet FETs, horizontal gate all around (HGAA) FETs, vertical gate all around (VGAA) FETs, among other FET devices. An active region of a semiconductor device can generally be considered a region where one or more transistors are formed. In some cases, a separation or isolation is disposed between active regions of a semiconductor device. An opening of a semiconductor device can be disposed between neighboring active regions of the semiconductor device. Conversely, active regions of a semiconductor device can be disposed between openings of the semiconductor device. In some forms, one or more openings can be formed by etching through an area of a semiconductor device and filling openings with one or more dielectric materials.

In some methods of manufacturing a semiconductor device including fin FETs or sheet FETS, openings can be formed by performing a fin-cut or sheet-cut process and filling the fin-cut or sheet-cut regions with one or more dielectric materials. In some embodiments, a fin-cut or sheet-cut etching process that cuts a sacrificial gate material such as polysilicon is referred to as Continuous Poly on Diffusion Edge (or Cut Poly on Diffusion Edge) (CPODE) etching process. In some embodiments, a fin-cut or sheet-cut etching process that cuts through a metal gate is referred to as a Continuous Metal on Diffusion Edge (or Cut Metal on Diffusion Edge) (CMODE) etching process. A diffusion edge can be referred to as an active edge, i.e., an edge abutting adjacent active regions. Also, a process that cuts through a metal gate can be referred to as a Cut Metal Gate (CMG) process.

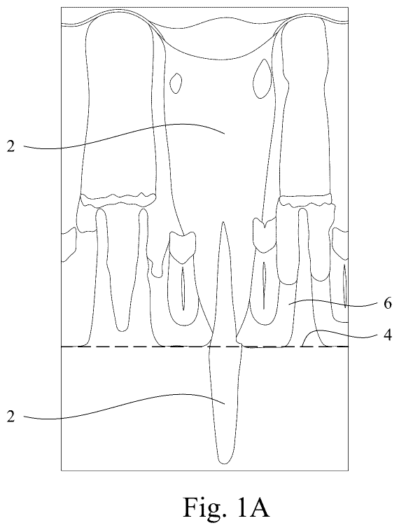

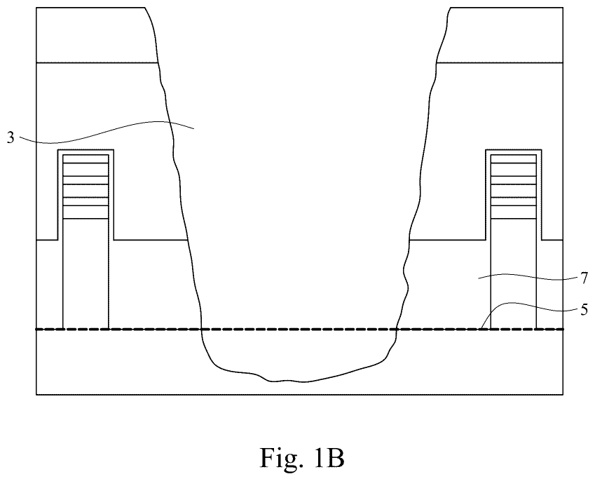

A CPODE or CMODE etching process can be used to reduce gate pitch, thereby increasing the density for multi-gate devices and thus device performance required for aggressively scaled circuits and devices. A CPODE or CMODE etching process can be used to pattern transistors to avoid leakage current through epitaxially formed source/drain structures or regions, transistors, and silicon substrates. A CPODE or CMODE etching process can form an opening having a deep etch profile and a high aspect ratio, e.g., a triangular or narrow funnel-shaped profile, to isolate current leakage from source to drain passing through a silicon substrate. By carefully controlling and minimizing minor head loss of etchants during a CPODE or CMODE etching process, an opening having a high aspect ratio can be formed. FIG. 1A illustrates an embodiment of an opening 2 formed by a CPODE or CMODE process in a fin FET device. The opening 2 extends below a depth 4 of shallow trench isolation (STI) regions 6. FIG. 1B illustrates an embodiment of an opening 3 formed by a CPODE or CMODE process in a sheet FET device. The opening 3 extends below a depth 5 of (STI) regions 7.

A CPODE or CMODE etching process can form an opening having a high aspect ratio by minimizing at least minor head loss of fluid or plasma etchants during the etching process. Generally, minimizing minor head loss can minimize abrupt changes in the shape of an opening such as a trench or etch profile in a substrate when viewed as a cross-section along an etching direction through the etched area.

In some forms, the relationships between major head loss and minor head loss can be expressed by the following equations and variables.

Revised Bernoulli Equation (energy of fluid without major & minor loss):

$$P + \frac{ρ {v}^{2}}{2} + h + ρ gh + qEh$$

where P is absolute pressure, ρ is fluid density, ν is velocity of fluid, h is height above a reference point, g is acceleration due to gravity, q is electric charge density, and E is electric field.

Revised Darcy-Weisbach Equation (energy of fluid with major & minor loss):

$$\frac{{P}_{i}}{ρ g} + \frac{{v}_{i}^{2}}{2 g} + {h}_{i} + \frac{{qEh}_{i}}{ρ g} = \frac{{P}_{f}}{ρ g} + \frac{{v}_{f}^{2}}{2 g} + {h}_{f} + \frac{{qEh}_{f}}{ρ g} + {h}_{major loss} + {h}_{minor loss}$$

where h_{f} is final height, hᵢ is initial height, P_{f} is final pressure, Pᵢ is initial pressure, νⱼ is final velocity, νᵢ is initial velocity, ρ is density of fluid, g is acceleration due to gravity, q is electric charge density, E is electric field, and A is cross-sectional area.

### Major Loss:

$${h}_{major loss} = f \times ( \frac{length of the tunnel}{hydraulic diameter of the tunnel} ) \times ( \frac{{v}^{2}}{2 ( g + \frac{QE}{m} )} )$$

where f is Darcy-Weisbach friction coefficient, ν is velocity, g is acceleration due to gravity, [symbol] is charge carried by etchants, E is electric field, and m is mass.

While the term tunnel is used in the equation above, any etched structure, such as a tunnel, opening, hole, cavity, or trench, can be applied in the formula. Without intending to be bound by any particular theory, major loss is thought to be caused by friction of etchants against the surface of a structure being etched, such as such as a tunnel, opening, hole, cavity, or trench.

### Minor Loss:

$${h}_{minor loss} = K \times ( \frac{{v}^{2}}{2 ( g + \frac{QE}{m} )} )$$

where K is minor loss coefficient, ν is velocity, g is acceleration due to gravity, [symbol] is charge carried by etchants, E is electric field, and m is mass.

Without intending to be bound by any particular theory, the following is noted regarding minor loss. Minor loss is thought to be caused by a shape change, e.g., a cross-sectional shape change, in a structure being etched along an etching direction, and turbulent flow in etchants or other material due to the change in shape. The change in shape might include a joint, constriction, abutment, or bottleneck within a structure being etched. It is thought that the change in shape induces minor loss through turbulent flow induced by the impingement of etchants on the area having the change in shape. When considering energy loss as h_{minor loss}, it is generally thought that a relatively larger change in a cross-sectional area of an etched structure along an etching direction causes relatively higher h_{minor loss} whereas a relatively smaller change in cross-sectional area of an etched structure along an etching direction causes relatively smaller h_{minor loss}. It is also generally thought that a relatively abrupt change in a cross-sectional area of an etched structure along an etching direction causes relatively higher h_{minor loss}, whereas a relatively gradual change in a cross-sectional area of an etched structure along an etching direction causes relatively smaller h_{minor loss}.

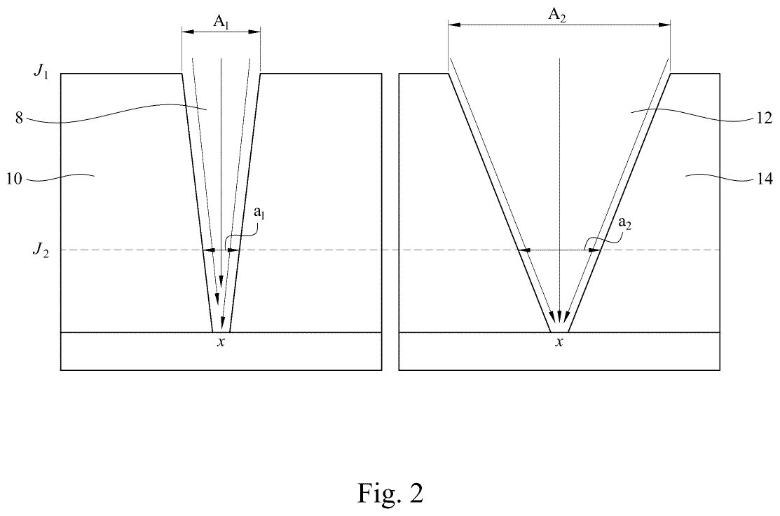

FIG. 2 illustrates cross-sections taken along an etching direction through an embodiment of a first etch profile (1) including an etched opening 8 in a substrate 10 and a second etch profile (2) including an etched opening 12 in a substrate 14. Both the first and second etch profiles terminate at X in the etched openings 8,12. Downward pointing arrows within both etch profiles (1) and (2) schematically illustrate the general directions of at least some etchants during an etching process. The opening 8 of the first etch profile (1) has a relatively smaller cross-sectional area A₁ at level J₁ when compared with the opening 12 of the second etch profile (2) having cross-sectional area A₂ at level J₁. Similarly, the opening 8 of etch profile (1) has a relatively smaller cross-sectional area α₁ at level J₂ when compared with the cross-sectional area α₂ at level J₂ of opening 12 of the second etch profile (2).

Without intending to be bound by any particular theory, the following distinctions are also thought to exist between etch profile (1) and etch profile (2) shown in FIG. 2. When considering energy loss as h_{minor loss}, etch profile (1) is thought to have higher h_{minor loss} during etching at level J₁ when compared with etch profile (2) at level J₁, because the cross-section area A₁ of the opening 8 of etch profile (1) is smaller than the cross-sectional area A₂ of the opening 12 of etch profile (2). In contrast, etch profile (1) is thought to have a lower h_{minor loss} during etching at level J₂ when compared with etch profile (2) due to the more gradual change in the shape of the opening 8 along the etching direction from level J₁ to level J₂ when compared with the more rapid change in the shape of the opening 12 along the etching direction from level J₁ to level J₂ in etch profile (2). A change in the shape of etching structure (1) can be considered to be a rate at which a cross-sectional area of the etched opening 8 changes from the area A₁ at level J₁ to the area α₁ at level J₂. When compared with the rate of change in etching structure (1), etching structure (2) has a more rapid change in shape in the direction of etching from level J₁ having area A₂ to level J₂ having area α₂.

Without intending to be bound by any particular theory, the following points are noted. It is generally thought that minor head loss (h_{minor loss}) can be prominent in etch processes utilizing high-density plasma at low pressure (e.g., 0.1 mT-100 mT). With the downsizing of devices and etch profiles, it is thought that etch profiles having relatively smaller critical dimensions (CD) produce relatively higher minor head loss when compared with etch profiles having relatively larger CD. For example, the smaller opening area A₁ at level J₁ of etching profile (1) in FIG. 2 is thought to generate relatively higher minor head loss than the opening area A₂ of etching profile (2).

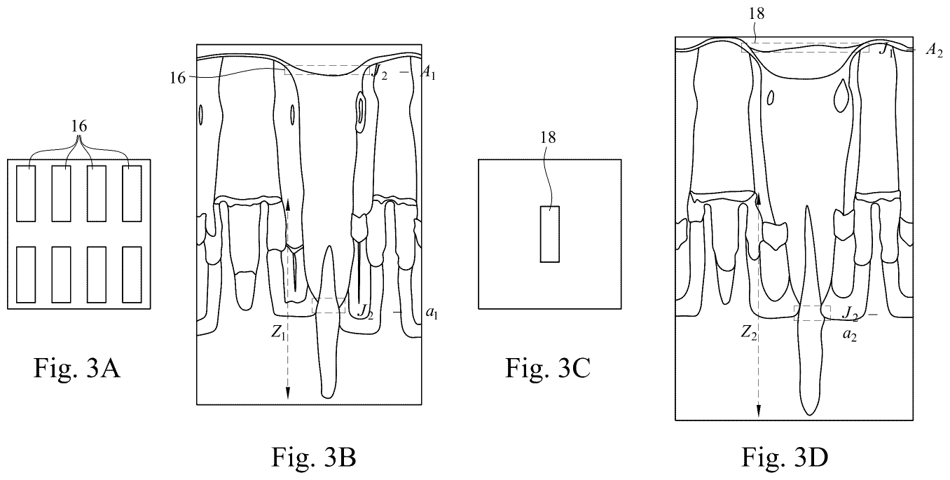

FIGS. 3A and 3C illustrate embodiments of patterns of openings 16, 18 in plan view. FIG. 3A illustrates a relatively high pattern density of openings (high open ratio), and FIG. 3C illustrates a relatively low pattern density of a single opening in the same area (low open ratio). FIGS. 3B and 3D respectively illustrate embodiments of openings 16, 18 formed using one or more etching processes as described herein, such as CPODE or CMODE etching processes. The cross-sections in FIGS. 3B and 3D are taken along etching directions of the openings 16, 18. Dimension Z₁ from a level at the top of fins shown in FIG. 3B can range from 160 nm to 200 nm, and dimension Z₂ from a level at the top of fins shown in FIG. 3D can range from 170 nm to 210 nm.

Without intending to be bound by any particular theory, the following points are noted. It is thought that minor head loss decreases when an etch profile has a gradual change in shape, such as the funnel-shaped etch profiles shown in FIGS. 3B and 3D. The cross-sections taken along the etching directions of etch profiles illustrated in FIGS. 3B and 3D have gradual changes in the shape from level J₁ (respectively having cross-section areas A₁ and A₂) to level J₂ (respectively having cross-section areas α₁ and α₂). It is thought that the funnel-shaped etch profiles substantially decrease minor head loss at level J₂. It is also thought that the minor head loss at level J₁ of the etch profile shown in FIG. 3B is greater than the minor head loss at level J₁ of the etch profile shown in FIG. 3D, because the area A₁ is smaller than the area A₂. However, it is thought that the minor head loss at level J₂ of the etch profile shown in FIG. 3D is greater than the minor head loss at level J₁ of the etch profile shown in FIG. 3B due to the more gradual change in the shape of the etch profile from level J₁ to level J₂ in the etch profile shown in FIG. 3B when compared with the etch profile in FIG. 3D.

In some forms, when considering a high-density pattern (high open ratio) illustrated in FIG. 3A, it is desirable to minimize minor head loss at level J₂ shown in FIG. 3B, i.e., minimization of minor head loss through a gradual change in the cross-sectional area from A₁ to α₁. In some forms, when considering a low-density pattern (low open ratio) illustrated in FIG. 3C, it is desirable to minimize minor head loss at level J₁ by providing the relatively larger cross-sectional area A₂ in FIG. 3D.

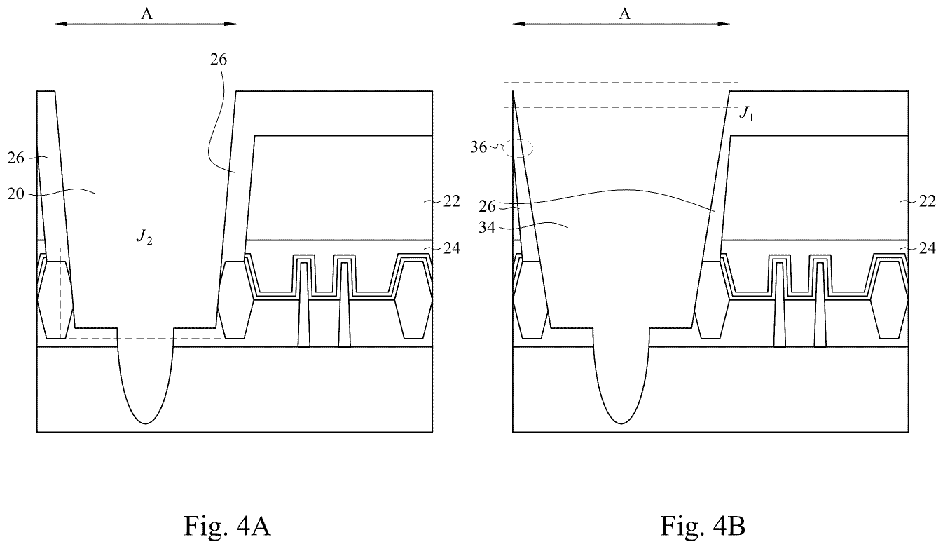

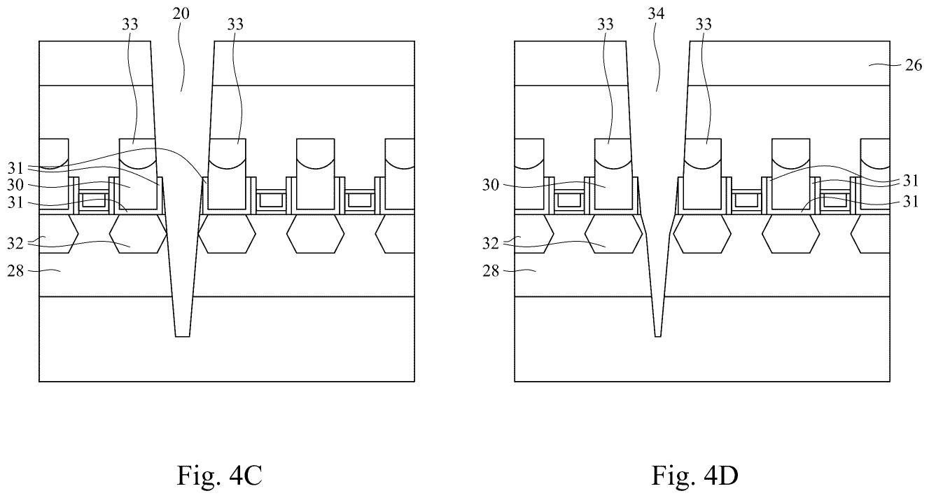

FIGS. 4A and 4B respectively illustrate different etching profiles at cross-sections taken along gate structures of fin FET devices having self-aligned contact (SAC) structures formed of amorphous silicon, according to some embodiments. The cross-section that is shown in FIG. 4A forms part of the device having a high-density pattern (high open ratio) of openings. The cross-section that is shown in FIG. 4B forms part of the device having a low-density pattern (low open ratio) of openings.

The opening 20 in the structure in FIG. 4A is formed by an etching process, such as by a CPODE or CMODE process, to minimize minor head loss at level J₂ by providing a gradual change in shape through the etch profile along the etching direction of the opening to permit high-density placement of openings in the device without etching structures such as an SAC layer 22 and a gate layer 24, which are separated from the opening by a mask layer 26.

The opening 34 in the structure in FIG. 4B is formed by an etching process, such as by a CPODE or CMODE process, to minimize minor head loss at level J₁ without exposing structures such as the SAC layer 22 or the gate layer 24, which are separated from the opening 34 by a mask layer 26. The opening 34 is etched without exposing the SAC layer at location 36.

In some embodiments, the cross-sectional areas (A) of the top of the openings shown in FIGS. 4A and 4B can be controlled by adjusting a pattern size in a EUV lithography process or a hard mask open etch process.

FIGS. 4C and 4D respectively illustrate cross-sections taken along a fin 28 of the structures shown in FIGS. 4A and 4B. Interlayer dielectric (ILD) layers 30 are provided over epitaxially-formed source/drain structures 32. Contact etch stop layers (CESL) 31 are provided in a region between the tops of the source/drain structures 32 and the ILD layers 30 and on the sidewalls of the ILD layers. In some forms, a CESL can be formed of silicon nitride. Hard mask layers 33 are formed over the top of the ILD layers 30.

FIG. 4C shows that the etching process does not damage the ILD layers 30 on either side of the opening 20. In some embodiments, a portion of the CESL 31 (e.g., between 0 to 3 nm thick) remains on the sidewalls of the ILD layers 30 facing the opening 20. In some embodiments, a portion of the SAC layer 22 (e.g., ranging between 0 to 3 nm thick) remains on a surface of the CESL 31 layer facing the opening 20, in a region below the level of the hard mask layer 33. In FIG. 4D, the etching process forming opening 34 does not damage ILD layers 30 or epitaxially-formed source/drain structures 32 on either side of the opening 34.

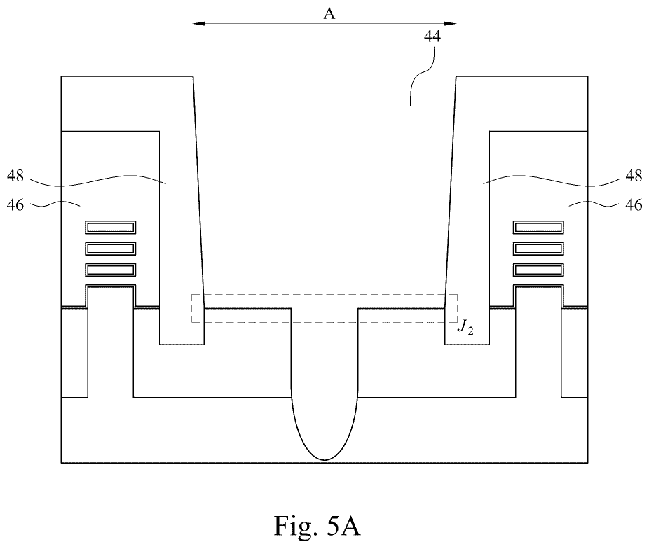

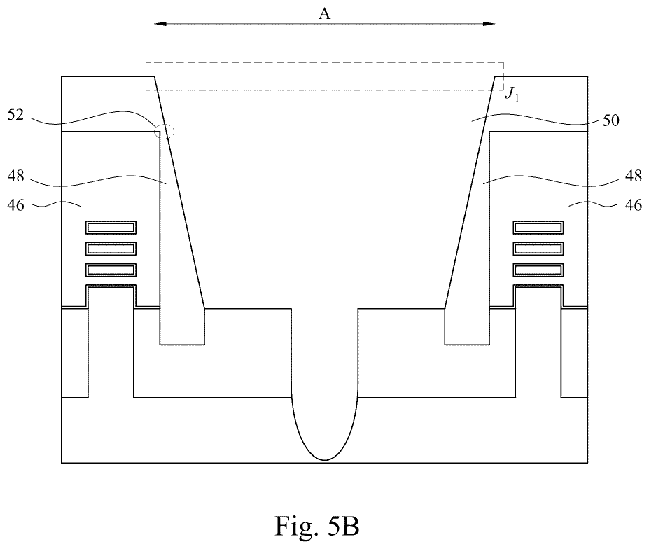

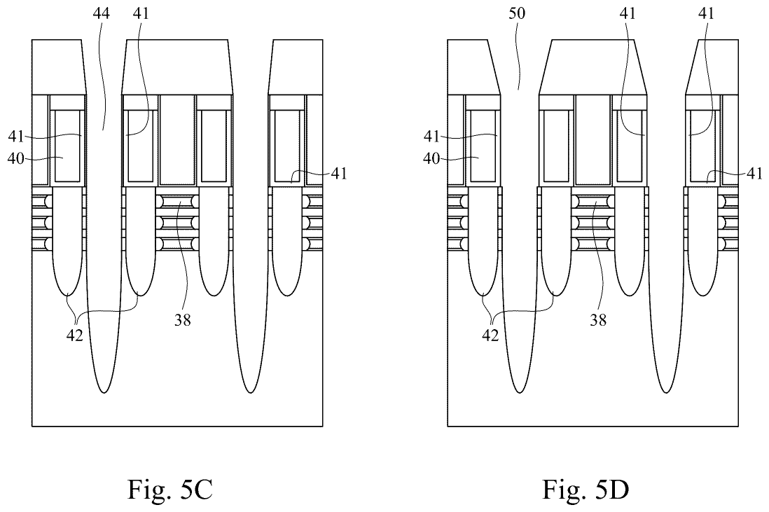

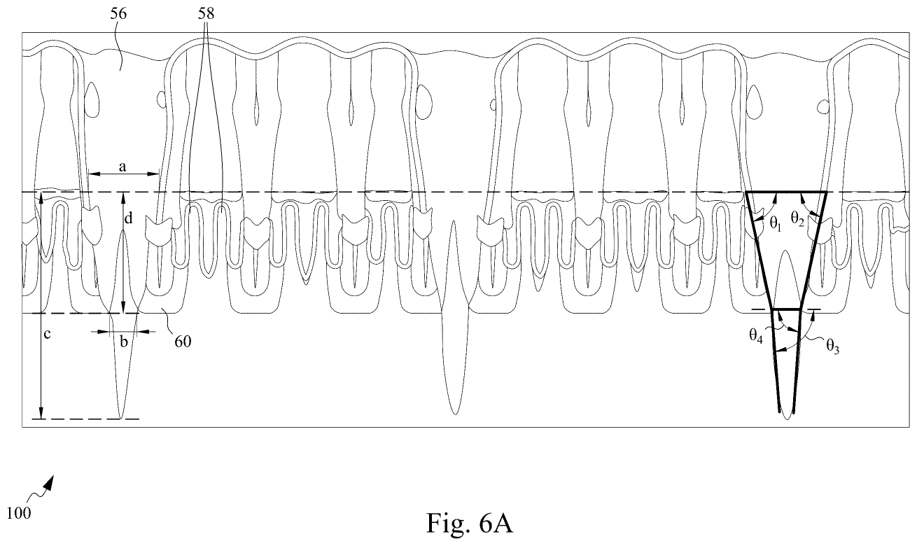

FIGS. 5A and 5B respectively illustrate different etching profiles at cross-sections taken along metal gate structures of sheet FET devices, according to some embodiments. The cross-section that is shown in FIG. 5A forms part of the device having a high-density pattern (high open ratio) of openings. The cross-section that is shown in FIG. 5B forms part of the device having a low-density pattern (low open ratio) of openings. In some embodiments, the cross-sectional areas (A) of the top of the openings shown in FIGS. 5A and 5B can be controlled by adjusting a pattern size in a EUV lithography process or a hard mask open etch process.

FIGS. 5C and 5D respectively illustrate cross-sections taken along sheet stacks 38 of the structure shown in FIGS. 5A and 5B. The opening 44 in the structure shown in FIG. 5A is formed by an etching process, such as by a CPODE or CMODE process, to minimize minor head loss at level J₂ by providing a gradual change in shape along the etching direction of the etch profile of the opening to permit high-density placement of openings in the device without exposing structures of a metal gate layer 46 separated from the opening by a mask layer 48.

The opening 50 in the structure shown in FIG. 5B is formed by an etching process, such as by a CPODE or CMODE process, to minimize minor head loss at level J₁ without exposing the metal gate 46 separated from the opening 50 by a mask layer 48. The opening 50 is etched without exposing the metal gate 46 at location 52.

FIGS. 5C and 5D respectively illustrate cross-sections taken along sheet stacks 38 of the structures shown in FIGS. 5A and 5B. FIGS. 5C and 5D illustrate ILD layers 40 provided over epitaxially-formed source/drain structures 42. FIGS. 5C and 5D also illustrate CESLs 41 provided in regions between the tops of the source/drain structures 42 and the ILD layers 40 and on the sidewalls of the ILD layers. In some forms, a CESL can be formed of silicon nitride. FIG. 5C shows that the etching process does not damage ILD layers 40, CESLs 41, or epitaxially-formed source/drain structures 42 on either side of the opening 44. FIG. 5D shows that the etching process does not damage ILD layers 40 or epitaxially-formed source/drain structures 42 on either side of the opening 50, and at least portions of the CESLs 41 remain on sidewalls of ILD layers 40 and facing the opening 50.

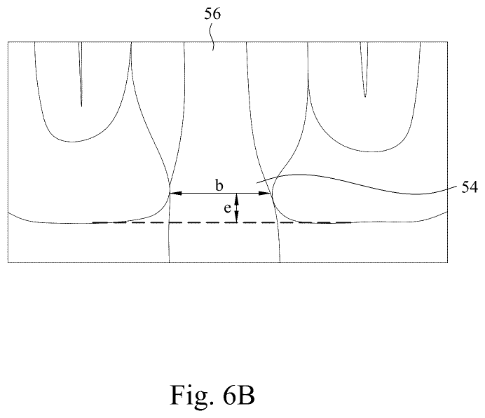

FIG. 6A illustrates a cross-section of an embodiment of a fin FET device taken along a metal gate after performing a CMODE etching process. FIG. 6B illustrates an enlargement of a bottle-neck 54 of an opening 56 where the “b” dimension is measured in FIG. 6A. Reference (a) corresponds to a width of an opening 56 at a level at the tops of fins 58. Reference (b) corresponds to a width of the opening at the bottle-neck 54. In some forms, a ratio of width (a) to width (b) ranges from about 2.8 to about 3.8, or from about 2.7 to about 3.4. Reference (c) corresponds to a depth of the opening measured from the level at the tops of fins 58 to the bottom of the opening. Reference (d) corresponds to a dimension of the opening from the level at the tops of fins 58 to a level at bottoms of STI regions 60. In some forms, a ratio of depth (c) to depth (d) ranges from about 1.7 to about 2, or from about 1.8 to about 1.9. Reference (e) corresponds to dimensions between a base of the bottle-neck within the opening to the level at the bottoms of the STI regions. In some forms, a ratio of width (b) to dimension (e) ranges from about 2.3 to about 5.8, or from about 2.4 to about 5.7. Angles (θ₁ and θ₂) correspond to slopes of opposite sides of the opening from the level at the tops of fins to the level at the bottoms of the STI regions. Angles (θ₃ and θ₄) correspond to slopes of opposite sides of the opening from the level at the bottoms of the STI regions to the bottom of the opening. In some forms, a ratio of one of the angles θ₁ and θ₂ to one of the angles θ₃ and θ₄ ranges from about 0.85 to about 0.95, or from about 0.87 to about 0.93.

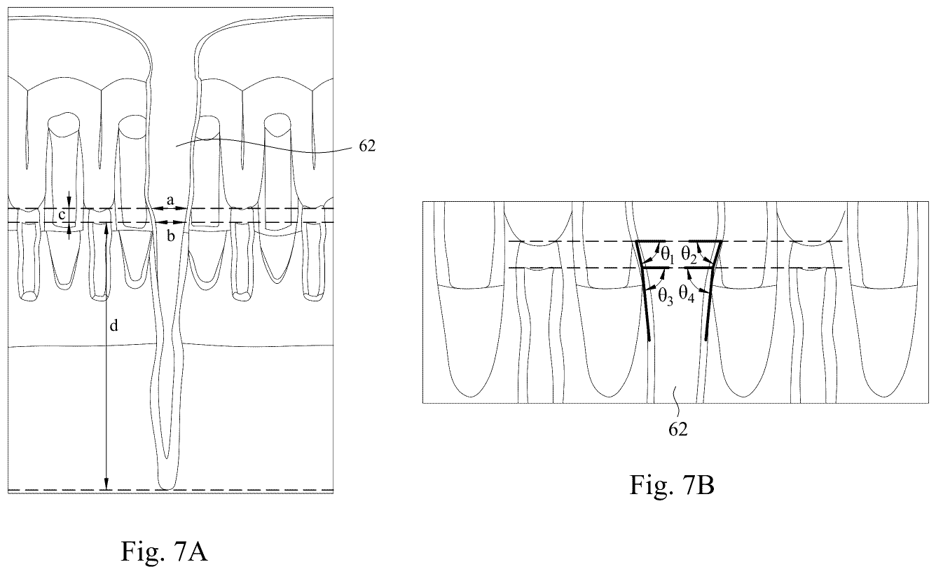

FIG. 7A illustrates a cross-section of an embodiment of a fin FET device taken along a fin after performing a CMODE etching process. FIG. 7B illustrates an enlarged view of a region of an opening 62 shown in FIG. 7A proximal to tops of fins and gate structures. Reference (a) corresponds to a width of an opening 62 at a level at the tops of gates. Reference (b) corresponds to a width of the opening 62 at a level at the tops of fins. In some forms, a ratio of width (a) to width (b) ranges from about 1.04 to about 1.18, or from 1.07 to about 1.16. Reference (c) corresponds to a depth of a constriction of a funnel feature of the opening measured from the level at the tops of gates to the level at the tops of fins. Reference (d) corresponds to a dimension of the opening from the level at the tops of fins to the bottom of the opening. In some forms, a ratio of depth (c) to dimension (d) ranges from about 0.02 to about 0.06, or from about 0.03 to about 0.05. Angles (θ₁ and θ₂) correspond to slopes of opposite sides of the opening from the level at the tops of gates to the level at the tops of the fins. Angles (θ₃ and θ₄) correspond to slopes of opposite sides of the opening from the level at the tops of the fins to the bottom of the opening. In some forms, a ratio of one of the angles θ₁ and θ₂ to one of the angles θ₃ and θ₄ ranges from about 0.9 to about 1, or from about 0.92 to about 0.99.

In some embodiments, a width of an opening decreases from a level at tops of the plurality of fins of a fin FET device to a level at bottoms of the plurality of STI regions when viewed at a cross-section taken along a direction in which a gate structure extends. In some embodiments, a width of an opening gradually and continuously decreases from a level at tops of a plurality of fins to a level at bottoms of the plurality of STI regions. In some embodiments, a width of an opening decreases from a level at tops of the stacks of sheet stacks to a level at bottoms of STI regions when viewed at a cross-section taken along a direction in which a gate structure extends. In some embodiments, a width of an opening gradually and continuously decreases from a level at the tops of sheet stacks to a level at the bottoms of the STI regions.

Any suitable etching conditions and etching devices can be used to conduct an etching process, such as a CPODE etching process or a CMODE etching process according to embodiments of the disclosure. In some embodiments, an etching process is conducted by applying high-density plasma generated within an etching device, such as an etching chamber, including inductively coupled plasma (ICP) coils, dipole antenna coils, or electron cyclotron resonance (ECR) magnetrons. In embodiments, useful operating frequencies of bias power for ICP and dipole antenna etching devices range from 1 MHz to 35 MHz, 1 MHz to 27 MHz, or 2 MHz to 13.6 MHz. In some embodiments, suitable operating frequencies of bias power for ECR etching devices range from 200 KHz to 700 KHz, 350 KHz to 500 KHz, and 250 KHz to 700 KHz in other embodiments.

In some forms, an etching process, such as a CPODE etching process or a CMODE etching process, can be conducted in a plasma etching device, including ECR magnetrons, operating at low pressures to achieve highly directional and anisotropic etching. The plasma etching is conducted in a process chamber at a pressure ranging from about 0.1 mTorr to about 150 mTorr in some embodiments, from about 0.2 mTorr to about 100 mTorr in some embodiments, from about 0.3 mTorr to about 80 mTorr or less than about 50 mTorr in other embodiments. Plasma etching is conducted in a process chamber at a temperature ranging from about 10 degrees Celsius to about 130 degrees in some embodiments, from about 20 degrees Celsius to about 120 degrees Celsius in some embodiments, or from about 30 degrees Celsius to about 100 degrees Celsius in other embodiments. The plasma etching is conducted while applying power, from an RF power generator, ranging from about 75 W to about 2600 W in some embodiments, from about 0 W to about 2500 W in some embodiments, or from 200 W to about 1100 W in other embodiments. Pulsed plasma etching is conducted with a duty cycle ranging from about 2% to about 98% in some embodiments, about 5% to about 95% in some embodiments, or from about 10% to about 90% in other embodiments. In some embodiments, the plasma etching is conducted while applying RF bias power to a pedestal ranging from about 0 W to about 2500 W, from about 100 W to about 2000 W, or from about 1500 W to about 1500 W. At pressures, temperatures, and powers outside the disclosed ranges, there may be insufficient etching or damage to the semiconductor device components.

In embodiments of the disclosure, the etching process, such as the CPODE etching process or the CMODE etching process, uses any suitable etchant species or combinations thereof. In some forms, a CMODE or CPODE etching for etching silicon can use HBr or Cl₂, with an optional addition of O₂ or CO₂. In some aspects, control of one or more critical dimensions can be achieved by forming SiO(Br) passivation layers by adding SiCl₄, HBr, and O₂ during etching. After the deposition of passivation layers, highly directional break through steps with etchants having low selectively, such as CF₄, C₄F, CH₃F, CH₂F₂ and CHF₃, can be used to remove the passivation layers in the etch front and facilitate the continued etch of silicon. An etching process forming passivation layers, breaking through and removing passivation layers can be conducted in cyclic steps, e.g. a process repeating the formation of a passivation layer and breaking through the passivation layer in cycles.

Various etching conditions can be used during an etching process, such as a CMODE or CPODE etching process, to achieve low energy loss, e.g., low minor head loss, and produce an opening having a low energy loss etch profile exhibiting a gradual change of cross-sectional area, e.g., a funnel-shaped or triangular profile according to embodiments of the disclosure. In some forms, an etching process can produce an opening having a low energy loss etch profile by conducting a series of etching steps with progressively increased pressure or progressively decreased temperature. In some aspects, the pressure can be increased while performing an etching step. In some forms, the pressure can be held constant during a first etching step and increased during a subsequent etching step. In some aspects, the temperature can be decreased while performing the etching step. In some forms, temperature can be held constant during a first etching step and decreased during a subsequent etching step.

In some aspects, the etching process can produce an opening having a low energy loss etch profile by conducting steps with increasing etch selectivity, such as a series of etching steps performed with etchant recipes having progressively increased etching selectivity of silicon over one or more silicon dioxide and silicon nitride. In some embodiments, the etching process produces increasing etch selectivity through a series of etching steps by etching with an etchant including Cl₂ or BCl₃ during the initial etching steps and then using an etchant including HBr in subsequent etching steps.

Etching operations according to embodiments of the disclosure produce an opening with a relatively large cross-section area at the top of the opening by performing etching steps under low pressure, high temperature, or with etchants having low etching selectivity for specific materials, such as silicon. The etching operation further produces an opening with a relatively small cross-section area within the opening at a distance from the top of the opening by etching under high pressure and low temperature, or through highly selective etching steps. In some embodiments, a low energy loss profile, e.g., a funnel-shaped or triangular profile, is achieved using very low pressure in the main etch step of silicon (e.g., below about 50 mTorr). Such low pressure can be achieved by using modern tools capable of generate high density plasma in low pressure, such as ECR tools among other tools.

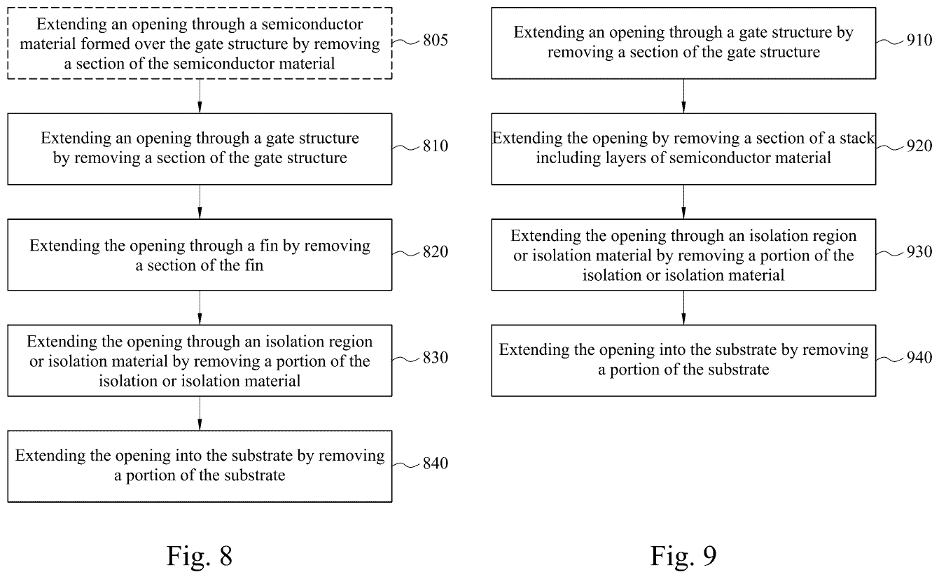

FIG. 8 illustrates a flow chart of an embodiment of an etching process according to the present disclosure. The etching process can include a CPODE or CMODE etching process. The etching process can be performed on any structure during the manufacture of a fin FET semiconductor device. The etching process shown in FIG. 8 includes extending 810 an opening through a gate structure by removing a section of the gate structure extending in a second direction. The gate structure may include a metal gate or a sacrificial gate. The etching process can include a CPODE process when etching a sacrificial gate or can include a CMODE process when etching a metal gate. The etching process shown in FIG. 8 further includes extending 820 the opening through a fin by removing a section of the fin extending in a first direction, wherein the first direction crosses the second direction. Also, extending an opening through the fin by removing a section of the fin can be performed without exposing source/drain structures on opposite sides of the opening along the first direction. The etching process shown in FIG. 8 further includes extending 830 the opening through STI region by removing a portion of the STI region, and extending 840 the opening into the substrate by removing a portion of the substrate. An opening formed using the etching process illustrated in FIG. 8 extends through the gate structure, the fin, and the STI region, and to a depth in the substrate below the STI region. The etching process can also extend the opening below source/drain structures of a fin FET device. The etching process in FIG. 8 can optionally extend 805 an opening through a semiconductor material formed over the gate structure by removing a section of the semiconductor material.

FIG. 9 illustrates a flow chart of an etching process according to an embodiment of the disclosure. Generally, the etching process can include a CPODE or CMODE etching process. The etching process can be performed on any structure during the manufacture of a sheet FET semiconductor device, such as a nanosheet FET semiconductor device. The etching process shown in FIG. 9 includes extending 910 an opening through a gate structure by removing a section of the gate structure extending in a second direction. A gate structure can include a metal gate or a sacrificial gate. The etching process can include a CPODE process when etching a sacrificial gate or can include a CMODE process when etching a metal gate. The etching process shown in FIG. 9 further includes extending 920 the opening by removing a section of a stack including layers of semiconductor material extending along a first direction, wherein the first direction crosses the second direction. Also, removing a section of stack can be performed without exposing source/drain structures on opposite sides of the opening along the first direction. The etching process shown in FIG. 9 further includes extending 930 the opening through an STI region by removing a portion of the STI region, and extending 940 the opening into the substrate by removing a portion of the substrate. An opening formed using the etching process illustrated in FIG. 9 extends through a gate structure, a stack, and an STI region, and to a depth in the substrate below the STI region. The etching process can also extend the opening below source/drain structures of a sheet FET device.

In some aspects, an etching process includes decreasing the etching temperature during the etching process. In some embodiments, an etching process includes continuously decreasing the etching temperature throughout performing one or more sequential stages of the etching process. In some embodiments, an etching process includes maintaining etching temperatures constant during each respective stage of two or more sequential stages of the etching process while conducting a later stage of the two or more sequential stages at a lower etching temperature than an etching temperature during a previous stage of the two or more sequential stages. In some forms, the sequential stages coincide with removal of different components of a structure of a semiconductor device during the etching process. In some embodiments, an etching temperature when extending an opening through a semiconductor material formed over a gate structure is higher than an etching temperature when extending the opening through the gate structure. In some embodiments, an etching temperature when extending an opening through a gate structure is higher than an etching temperature when extending the opening through a fin or sheet stack. In some embodiments, an etching temperature when extending an opening through a fin or sheet stack is higher than an etching temperature when extending the opening through an STI region. In some embodiments, an etching temperature when extending an opening through an STI region is higher than an etching temperature when extending the opening into a substrate.

In some aspects, an etching process includes increasing the etching pressure during the etching process. In some embodiments, an etching process includes continuously increasing the etching pressure throughout performing one or more sequential stages of the etching process. In some embodiments, an etching process includes maintaining etching pressures constant during each respective stage of two or more sequential stages of the etching process while conducting a later stage of the two or more sequential stages at a higher etching pressure than an etching pressure during a previous stage of the two or more sequential stages. In some forms, the sequential stages of an etching process coincide with the removal of different components of a structure of a semiconductor device during the etching process. In some embodiments, an etching pressure when extending an opening through a semiconductor material formed over a gate structure is lower than an etching pressure when extending the opening through the gate structure. In some embodiments, an etching pressure when extending the opening through a gate structure is lower than an etching pressure when extending the opening through a fin or sheet stack. In some embodiments, an etching pressure when extending an opening through a fin or sheet stack is lower than an etching pressure when extending the opening through an STI region. In some embodiments, an etching pressure when extending an opening through an STI region is lower than an etching pressure when extending the opening into a substrate.

In some aspects, an etching process includes increasing pressure and decreasing temperature during the etching process consistent with any combination of embodiments of increasing pressure and decreasing temperature during an etching process in the present disclosure. In some embodiments, one or more of the following conditions are met during an etching process: an etching temperature when extending an opening through a semiconductor material formed over a gate structure is higher than an etching temperature when extending the opening through the gate structure, an etching temperature when extending an opening through a gate structure is higher than an etching temperature when extending the opening through a fin or sheet stack, an etching temperature when extending an opening through a fin or sheet stack is higher than an etching temperature when extending the opening through an STI region, an etching temperature when extending an opening through an STI region is higher than an etching temperature when extending the opening into a substrate, an etching pressure when extending an opening through a semiconductor material formed over a gate structure is lower than an etching pressure when extending the opening through the gate structure, an etching pressure when extending the opening through a gate structure is lower than an etching pressure when extending the opening through a fin or sheet stack, an etching pressure when extending an opening through a fin or sheet stack is lower than an etching pressure when extending the opening through an STI region, and an etching pressure when extending an opening through an STI region is lower than an etching pressure when extending the opening into a substrate.

In some aspects, an etching process includes increasing etching selectivity of silicon over silicon oxide or silicon nitride over the course of the etching process. In some embodiments, this is achieved through initial etchant formulations used in early etching stages including a high concentration of Cl₂ or BCl₃ and etchant formulations used in later etching stages of the etching process having high concentrations of HBr. In some forms, each stage of the etching process includes a different etchant formulation, where an initial stage uses an etchant formulation having a high proportion of Cl₂ and the etchant formulation in each subsequent etching stage has a lower proportion of Cl₂. In some aspects, the etchant formulation of an initial stage of the etching process includes a low proportion of HBr, and the etchant formulation in each subsequent etching stage has a higher proportion of HBr.

Description herein of a processing stage, e.g., a first, second, or third stage of a process, such as a CPODE or CMODE etching process, does not preclude intermediate processing from being performed on a structure between sequentially numbered stages. Moreover, description herein of a first stage of a process, such as a CPODE or CMODE process, does not preclude earlier processing being performed on a structure before the first stage. Also, description herein of a sequence of processing stages appearing to include a last stage of the described sequence of processing stages does not preclude subsequent processing of a structure produced by the sequence of processing stages. Moreover, any intermediate, earlier, or subsequent processing may include any one or more processes useful for producing a structure, including any one or more additional CPODE or CMODE processes. Further, processing stages can be reordered or and one or more processing stages can be omitted as desired.

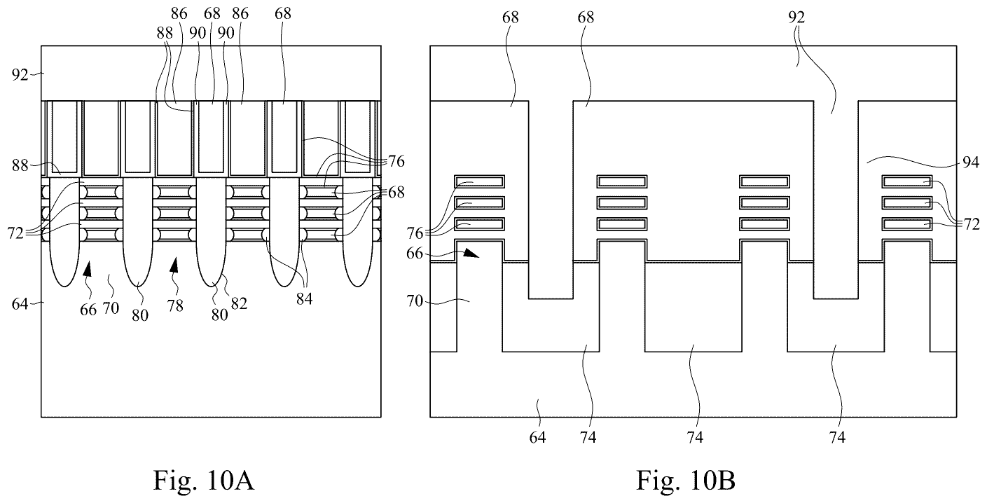

FIGS. 10A, 11A, 12A, 13A, 14A, 15A, 16A, and 17A illustrate cross-sections of structures at sequential stages of a method of manufacturing a semiconductor device including a plurality of sheet FET devices, according to some embodiments. The cross-sections shown in FIGS. 10A, 11A, 12A, 13A, 14A, 15A, 16A, and 17A are taken along a sheet stack of the plurality of the sheet FET devices, with the sheet stack extending in a first direction. FIGS. 10B, 11B, 12B, 13B, 14B, 15B, 16B, and 17B illustrate cross-sections taken along a metal gate structure of the structures respectively shown in FIGS. 10A, 11A, 12A, 13A, 14A, 15A, 16A, and 17A, with the metal gate structure extending in second direction crossing the first direction.

FIGS. 10A and 10B illustrate cross-sections of a structure including a substrate 64. The substrate 64 may be a semiconductor substrate, such as a bulk semiconductor, a semiconductor-on-insulator (SOI) substrate, or the like, which may be doped (e.g., with a p-type or an n-type dopant) or undoped. The substrate may be a wafer, such as a silicon wafer. Generally, an SOI substrate can include a layer of a semiconductor material formed on an insulator layer (not shown). The insulator layer can be, for example, a buried oxide (BOX) layer, a silicon oxide layer, or the like. The insulator layer can be provided on a substrate, such as a silicon or glass substrate. Other substrates, such as a multi-layered or gradient substrate can also be used. In some embodiments, a substrate includes a semiconductor material. In some forms, the semiconductor material of the substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. The substrate may also include structural additional features or components not illustrated in the drawings.

The embodiment illustrated in FIGS. 10A and 10B includes sheet stacks 66 formed over the substrate 64. FIG. 10A illustrates a cross-section of a stack 66 extending in the first direction, and FIG. 10B illustrates a plurality of stacks 66 taken in a cross-section along a metal gate 68 extending in the second direction. The stacks 66 include bases 70 and a plurality of sheets 72 above the bases. In some forms, the sheets have the same composition as the bases and the substrate. FIG. 10B shows STI regions 74 formed about bases 70 of stacks 66. In some embodiments, an STI region includes an STI recess filled with one or more insulating materials. An STI recess can be formed by an etching process. In some embodiments, STI recesses are formed using a dry etching process using etchant gases such as HF and NH₃. During the etching process, plasma may be generated. Argon may also be included during the etching process. In some embodiments, the STI recesses are formed using a wet etch process using HF. STI regions can include a liner oxide (not shown), which may be a thermal oxide formed through a thermal oxidation of a surface layer of substrate. The liner oxide may also be a deposited silicon oxide layer formed using, for example, atomic layer deposition (ALD), chemical vapor deposition (CVD), high-density plasma chemical vapor deposition (HDPCVD), flowable chemical vapor deposition (FCVD), or the like. STI regions can also include a dielectric material over the liner oxide, wherein the dielectric material may be formed using FCVD, spin-on coating, or the like. In some forms, a dielectric material such as SiOx, SiN, SiCN, SiOCN, and SiGeOx can be used to fill an STI region. A liner may be formed in the STI region and a dielectric material formed over the liner can each independently be any type of insulating material, including various oxides, such as silicon oxide, a nitride, or other insulators, or combinations thereof. Other dielectric materials and other formation processes may be used.

The embodiment illustrated in FIGS. 10A and 10B includes a gate dielectric 76 formed over portions of the STI regions and bases 70 of the stacks 66. The gate dielectric covers and surrounds the sheets 72 in a channel region 78 of the stacks 66. The gate dielectric may include silicon oxide, silicon nitride, or multilayers thereof. In some embodiments, the gate dielectric includes a high-k dielectric material. In some forms, the gate dielectric has a k value greater than about 7.0, and can include a metal oxide or a silicate of Hf, Al, Zr, La, Mg, Ba, Ti, Pb, or combinations thereof. The gate dielectric can be formed by any suitable process, such as molecular beam deposition (MBD), ALD, and the like. In some forms, a thickness of the gate dielectric ranges from about 8 angstroms (Å) to about 20 Å.

FIGS. 10A and 10B illustrate the metal gate 68 formed over the stacks 66 and covering and surrounding the sheets 72 in the channel region 78, with the gate dielectric 76 being disposed between the metal gate 68 and the sheets 72. In some forms, the metal gate is referred to as a work function layer, and can be a P-type work function layer, an N-type work function layer, multi-layers thereof, or combinations thereof. Example P-type work function metals that may be included in a metal gate for P-type devices include TiN, TaN, Ru, Mo, Al, WN, ZrSi₂, MoSi₂, TaSi₂, NiSi₂, WN, other suitable P-type work function materials, or combinations thereof. Example N-type work function metals that may be included in a metal gate for N-type devices include Ti, Ag, TaAl, TaAlC, TiAlN, TaC, TaCN, TaSiN, Mn, Zr, other suitable N-type work function materials, or combinations thereof.

FIG. 10A illustrates epitaxial source/drain structures 80 formed on opposite sides of the metal gate 68 and the sheets 72 at the channel region 78. Source/drain structures may refer to a source or a drain, individually or collectively depending upon the context. The illustrated epitaxial source/drain structures 80 are formed within recesses 82 extending into the substrate 64. The epitaxial source/drain structure can also extend relatively higher than the stack. The epitaxial source/drain structures can be formed in recesses by growing a strained material in the recesses by an epitaxial (epi) process. A lattice constant of the strained material may be different from the lattice constant of the substrate on which the epitaxial source/drain structures are formed. Accordingly, epitaxial source/drain structures can serve as stressors to improve carrier mobility. According to some embodiments, source/drain structures include silicon germanium, carbon-doped silicon, or silicon.

Depending on whether FET is a p-type FET or an n-type FET, a p-type or an n-type impurity may be in-situ doped during an epitaxy process, forming a source/drain structure. For example, when a resulting FET is a p-type FET, silicon germanium boron (SiGeB) may be grown. Conversely, when a resulting FET is an n-type FinFET, silicon phosphorous (SiP) or silicon carbon phosphorous (SiCP) may be grown. In some embodiments, source/drain structures may be implanted with a p-type or an n-type impurity as needed. Implantation can be skipped when source/drain structures are in-situ doped with the p-type or n-type impurity during the epitaxy forming source/drain structures. In some forms, source/drain structures include lower portions that are formed in STI regions, and upper portions that are formed over the top surfaces of STI regions.

FIG. 10A further illustrates inner spacers 84 disposed between the epitaxial source/drain structures 80 and regions of the metal gate between the sheets 72. Inner spacers may be formed of SiOCN, SiON, SiOC, SiCN, or the like. ILD layers 86 are formed over the epitaxial source/drain structures 80, and CESLs 88 are provided in a region between the tops of the source/drain structures 80 and the ILD layers 86 and on the sidewalls of the ILD layers. In some forms, the CESL is formed of silicon oxide, silicon nitride, silicon carbo-nitride, or the like or combinations thereof, and may be formed using CVD, ALD, or the like. In some forms, the ILD layers include a dielectric material formed using, for example, FCVD, spin-on coating, CVD, or any other suitable deposition method. In some forms, ILD layers are formed of an oxygen-containing dielectric material, which may include a silicon-oxide, phospho-silicate glass (PSG), boro-silicate glass (BSG), boron-doped phospho-silicate glass (BPSG), undoped silicate glass (USG), or the like. Formation of the CESL and ILD layers can include depositing a conformal CESL, depositing ILD layers, and performing a planarization process. FIG. 10A further illustrates a gate sidewall spacer 90 formed on opposite sides of the metal gate 68. In some forms, the gate sidewall spacers include a low-k dielectric material, such as silicon nitride, silicon carbo-nitride, or the like, and may have a single-layer structure or a multi-layer structure including a plurality of dielectric layers. The illustrated gate sidewall spacer 90 is disposed between the CESL 88 and the metal gate 68, and the CESL 88 is disposed between the gate sidewall spacer 90 and the ILD layer 86.

FIG. 10A illustrates a hard mask layer 92 formed over the metal gates 68, the CESL 88, and the sidewall spacers 90. FIG. 10B illustrates the structure in a configuration after performing a Cut Metal Gate process. The Cut Metal Gate process forms gate isolation cuts 94 through the metal gate 68 and into the STI regions 74. The Cut Metal Gate process serves to form isolated transistors. FIG. 10B illustrates the hard mask 92 is formed over the metal gate 68 and fills the gate isolation cuts 94. In some forms, a hard mask is formed of silicon nitride, silicon, silicon oxide, silicon carbo-nitride, silicon oxy-carbo-nitride, or combinations or multilayers thereof. In some forms, the hard mask is formed by any suitable process, such as low-pressure chemical vapor deposition (LPCVD), plasma-enhanced chemical vapor deposition (PECVD), or FCVD. After the hard mask is formed, the structure can be cleaned using a wet cleaning process including a cleaning agent, such as dilute hydrofluoric acid or an aqueous solution including ammonium hydroxide and hydrogen peroxide.

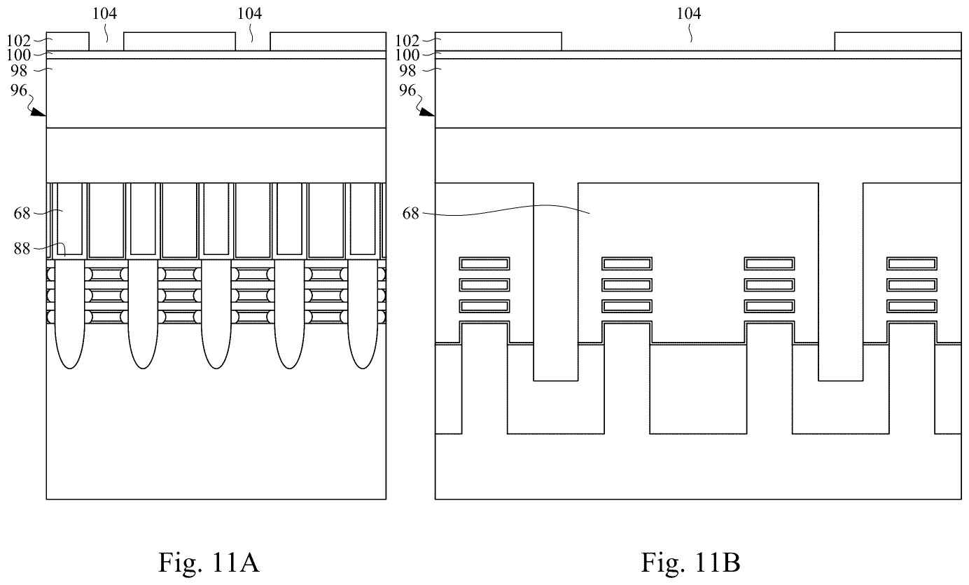

FIGS. 11A and 11B illustrate a tri-layer masking layer 96 formed over the hard mask 92. The tri-layer masking layer 96 includes a bottom layer 98, a middle layer 100 over the bottom layer, and an upper layer 102 over the middle layer. In some forms, the upper layer is formed of a photoresist (e.g., a photosensitive material), which includes organic materials, and may be a positive photosensitive material or a negative photosensitive material. In some forms, the photoresist layer includes a polymer, such as phenol formaldehyde resin, a poly(norbornene)-co-malaic anhydride (COMA), a poly(4-hydroxystyrene) (PHS), a phenol-formaldehyde (bakelite), a polyethylene (PE), a polypropylene (PP), a polycarbonate, a polyester, or an acrylate-based polymer, such as a poly(methyl methacrylate) (PMMA) or poly(methacrylic acid) (PMAA). In some forms, the upper layer including the photoresist may be formed by spin-on coating. In some forms, the photoresist layer may be patterned to form an opening therein. In some forms, the middle layer has a high etching selectivity relative to the upper layer and the bottom layer. In some forms, the middle layer includes an inorganic material, which may be a nitride (such as silicon nitride), an oxynitride (such as silicon oxynitride), an oxide (such as silicon oxide), or the like. In some forms, the bottom layer is formed using spin-on coating, CVD, PVD, ALD, or another suitable deposition technique. The bottom layer can include a carbon-based polymer material formed by spin-on coating. In some forms, the bottom layer is a bottom anti-reflective coating (BARC) layer or an ashing removal dielectric (ARD) layer (such as amorphous carbon). Different materials can be used such that optical properties and/or etching properties of the bottom layer and the middle layer are different from each other. In some forms, the bottom layer is a carbon layer and the middle layer is a silicon-rich layer designed to provide an etch selectivity between the middle layer and the bottom layer. Various layers of the tri-layer masking layer may be blanket deposited sequentially using, for example, spin-on processes. Other processes and materials may be used. Although a tri-layer masking layer is discussed herein, any suitable masking layer can be used. In some forms, a monolayer masking layer or a bilayer masking layer (e.g., including only a bottom layer and an upper layer without a middle layer) can be used. The type of masking layer used (e.g., monolayer masking layer, bilayer masking layer, or tri-layer masking layer) may depend on the photolithography process used, such as extreme ultraviolet (EUV) lithography processes.

FIGS. 11A and 11B illustrate the upper layer 102 including the photoresist after patterning to form openings 104. The upper layer can be patterned using any suitable photolithography process to form one or more openings therein. For example, a photomask (not shown) can be disposed over the upper layer, and upper layer may then be exposed to radiation such radiation in the form of an ultraviolet (UV) beam or an excimer laser, radiation from an EUV system, or an electron beam (e-beam) among others. One or multiple exposure steps can be performed, and a bake or cure operation can be performed to harden the upper layer. A developer can be used to remove either the exposed or unexposed portions of the upper layer depending on whether a positive or negative resist is used. One or more openings can be formed in a structure of a semiconductor device. The openings in FIGS. 11A and 11B are arranged at locations where a portion of the metal gate 68 is to be cut with a CMODE process.

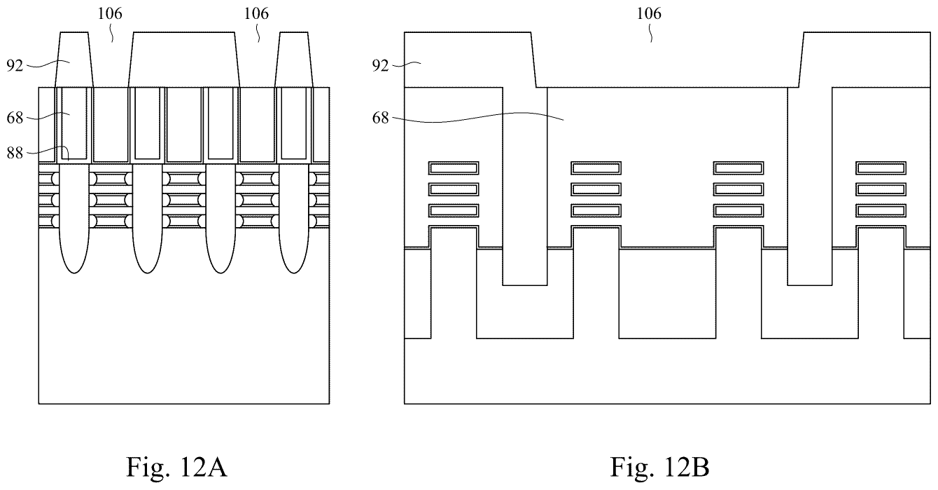

FIGS. 12A and 12B illustrate an embodiment of a structure of a semiconductor device upon removal of a section of the hard mask 92 by a first stage of the CMODE etching process. In both FIGS. 12A and 12B, openings 106 in the hard mask 92 have been formed using the upper layer 102 of tri-layer mask 96 as an etching mask. The first stage of the CMODE etching process can be a vertical dry etching process towards the metal gate 68, with the metal gate serving as an etch stop layer. Following the first stage of the CMODE process, the structure can be cleaned using a wet cleaning process such as a wet cleaning process as described herein.

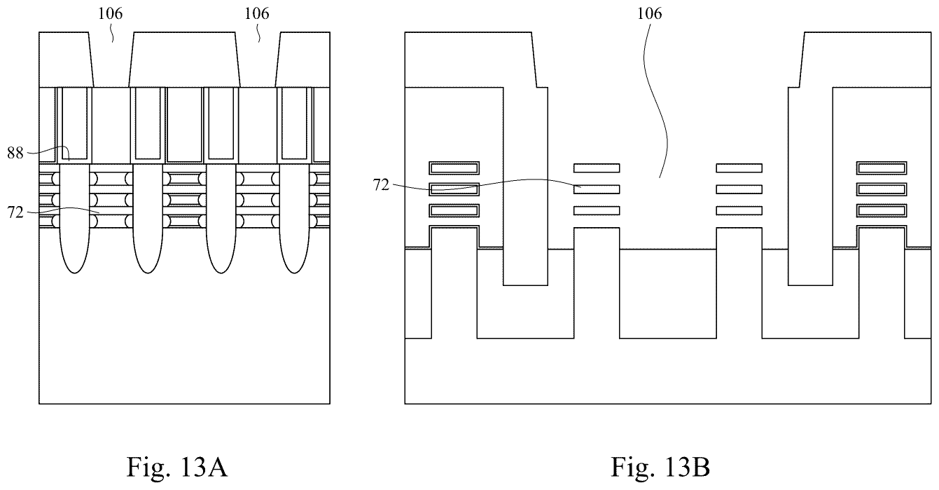

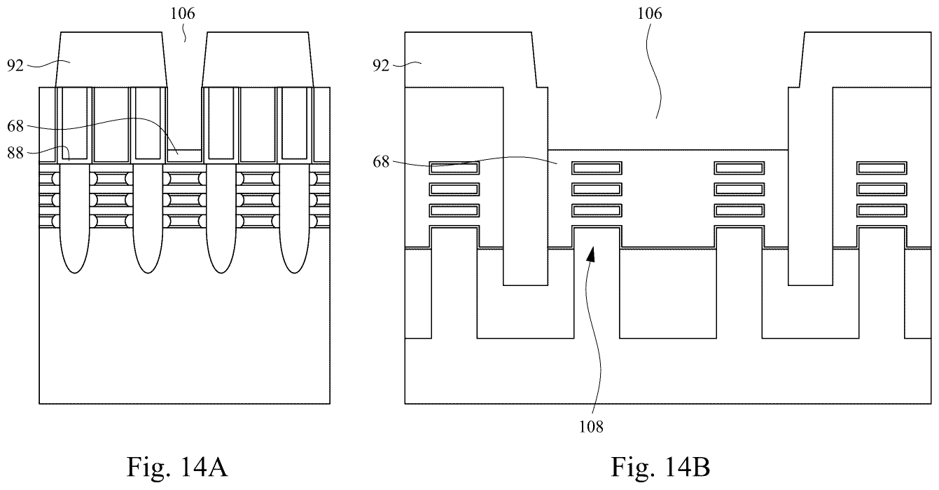

FIGS. 13A and 13B illustrate an embodiment of the disclosure following a second stage of a CMODE etching process to extend the openings 106 and to remove portions of metal gate 68 and gate dielectric 76. The metal gate 68 is removed from between the sheets 72 of the sheet stacks in the opening 105. FIGS. 14A and 14B illustrate an alternative embodiment following a second stage of the CMODE etching process to extend the opening 106 and partially remove the metal gate 68, while using the hard mask 92 as an etching mask. The second stage of the CMODE process illustrated in FIGS. 13A, 13B, 14A and 14B, can include a dry etch. Alternatively, a wet etch process can be used to obtain the structures in FIGS. 13A, 13B, 14A and 14B. After the etching to obtain the structures in FIGS. 13A, 13B, 14A and 14B, the structures can be cleaned using a wet cleaning process such as a wet cleaning process as described herein.

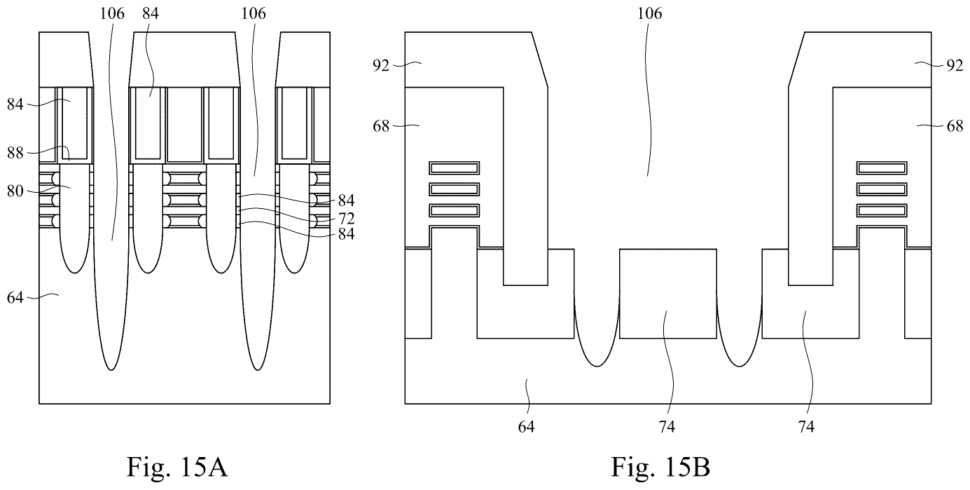

FIGS. 15A and 15B illustrate a structure after performing a third stage of a CMODE process on the structures shown in FIGS. 13A and 13B, respectively, to extend the openings 106 into the substrate 64. The third stage of the CMODE process removes portions of the substrate 64 positioned beneath the openings 106 defined by the hard mask 92 shown in FIGS. 13A and 13B. The openings 106 extend into the substrate to a depth below the STI regions 74 and the source/drain structures 80. As illustrated in FIG. 15A, the third stage of the CMODE process retains at least portions of the inner spacers 84 with portions of the sheets 72 therebetween at the level of the source/drain structures 80, and the opening 106 does not expose the source/drain structures 80. Also, the opening 106 does not expose the ILD layers 86 along the first direction. In some forms, the openings do not expose the CESL and retains at least a portion of the gate sidewall spacers lining walls of the opening. FIG. 15B illustrates that the opening 106 does not expose the metal gate 68 of both the adjacent FET devices along the second direction. The hard mask 92 is between the opening 106 and the metal gate 68 of both the adjacent FET devices along the second direction. The third stage of the CMODE process can include a directional anisotropic dry etch process. Following the third stage of the CMODE etching process, the structure can be cleaned using a wet cleaning process such as a wet cleaning process as described herein.

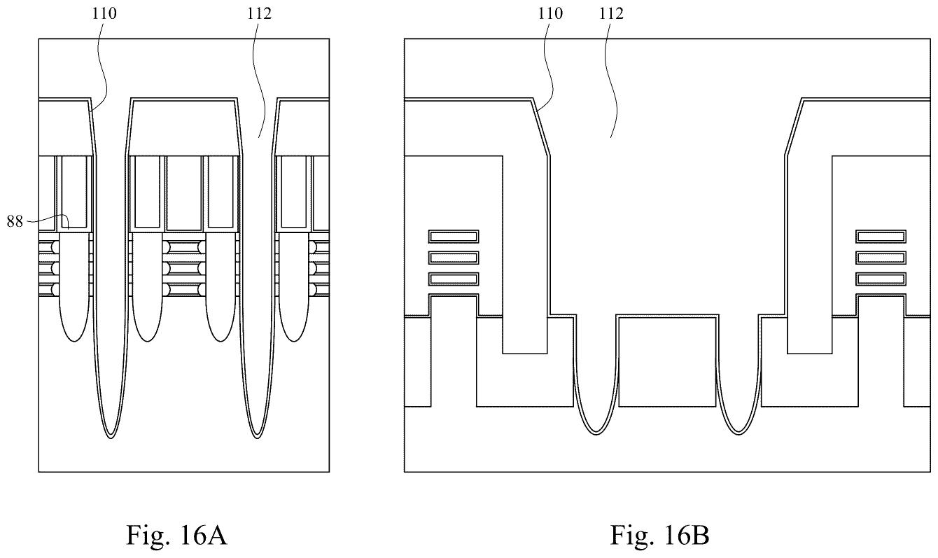

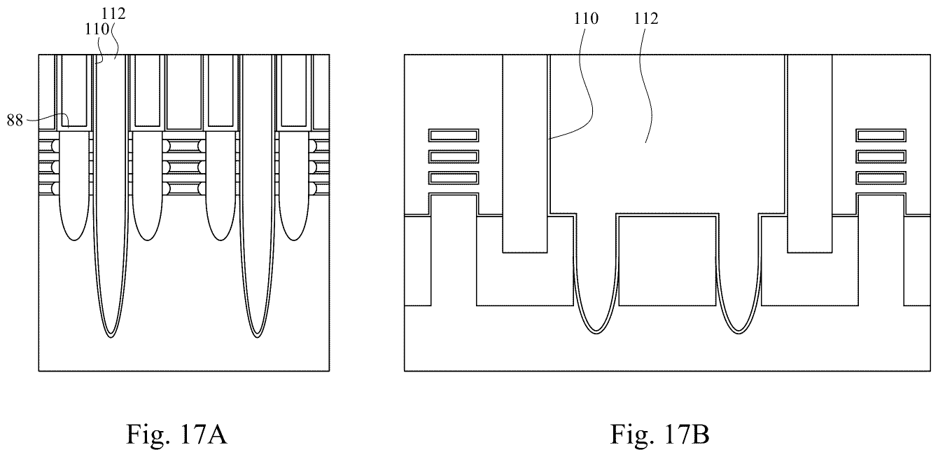

FIGS. 16A and 16B illustrate the formation of a conformal dielectric liner 110 in the opening and deposition of a dielectric fill 112 over the liner 110. The conformal dielectric liner can be any suitable dielectric material, including silicon oxide, silicon oxynitride, or the like, and can be formed using techniques such as ALD, CVD, PVD, or the like. The dielectric fill can be formed of silicon nitride, silicon oxynitride, silicon carbonitride, or the like. The dielectric fill can be formed using a suitable material deposition technique, such as ALD, CVD, PVD, FCVD, or the like. After forming the liner and dielectric fill, the structure can be cleaned by using any of the wet cleaning processes described herein. FIGS. 17A and 17B illustrate planarization of the structure shown in FIGS. 16A and 16B, respectively, using a planarization process, such as a chemical mechanical polishing (CMP) process.

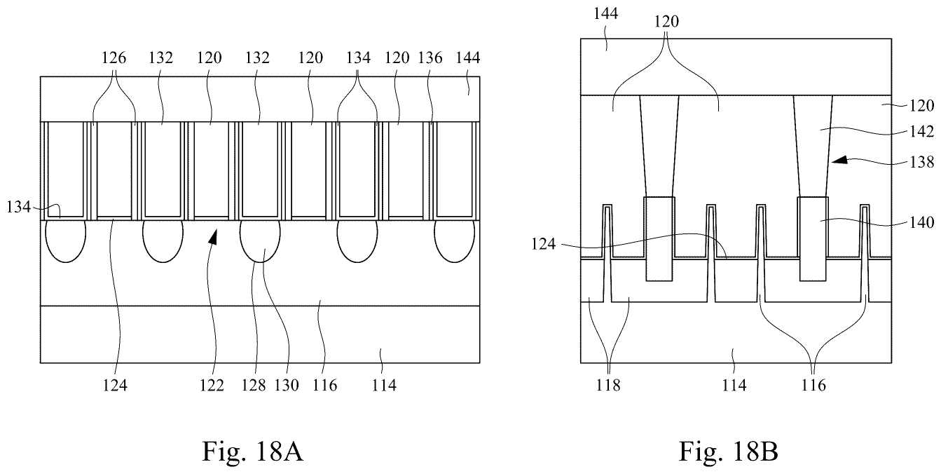

FIGS. 18A, 19A, 20A, 21A 22A, 23A, 24A, and 25A illustrate cross-sections of sequential stages of a method of manufacturing a semiconductor device including a plurality of fin FET devices, according to some embodiments. The cross-sections shown in FIGS. 18A, 19A, 20A, 21A 22A, 23A, 24A, and 25A are taken along a fin of the plurality of fin FET devices, with the fin extending in a first direction. FIGS. 18B, 19B, 20B, 21B 22B, 23B, 24B, and 25B illustrate cross-sections taken along a sacrificial gate of the structures respectively shown in FIGS. 18A, 19A, 20A, 21A 22A, 23A, 24A, and 25A, with the sacrificial gate extending in a second direction crossing the first direction.

FIGS. 18A and 18B illustrate a structure including a substrate 114 including a plurality of fins 116 extending above the substrate. A substrate and fin can include or be formed of any material or combination of materials and be formed by any process or combination of processes useful for forming substrate or fin, such as any material, process, or combination thereof described herein in connection with a substrate or fin. The fins 116 in FIGS. 18A and 18B were formed by patterning the substrate 114, and the material of the fins is the same as that of substrate. However, a dopant concentration in the fins 116 may differ from a dopant concentration in the substrate 114. In some forms, the dopant is a P-type or N-type dopant. In some forms, fins include dopant having an opposite polarity of a dopant in a substrate. In some forms, only one of the fins or the substrate will be doped. A concentration of dopant can be higher in the fins than the substrate, or a concentration of dopant can be higher in the substrate than the fins. In some forms, the substrate and fins include or are formed of a group IV semiconductor such as silicon, germanium, or a combination thereof.

FIG. 18B illustrates STI regions 118 disposed over the substrate and about the fins with the fins protruding from the STI regions. An STI region can include or be formed of any material or combination of materials and be formed by any process or combination of processes useful for forming STI region, such as any material, process, or combination thereof described herein in connection with an STI region. The STI regions 118 are recessed and top portions of fins 116 protrude higher than the top surfaces of the STI regions. In other embodiments, top surfaces of the fins and the top surfaces of STI regions are substantially level with each other. In other embodiments, the fins are replacement fins formed by etching the portions of the substrate between STI regions to form recesses, and epitaxially growing another semiconductor material to form fins in the recesses. Accordingly, grown fins can be formed of a semiconductor material different from that of substrate.

FIGS. 18A and 18B illustrate sacrificial gates 120 formed across and cover channel regions 122 of the fins 116. The sacrificial gates 120 also extend across the STI regions 118. In some forms, sacrificial gates extend in directions perpendicular to directions in which fins extend. The sacrificial gates shown in FIGS. 18A and 18B include a gate dielectric film 124 formed over the STI regions 118 and surfaces and sidewalls of protruding fins 116. The gate dielectric film 124 is formed in the bottom of recessed regions filled with sacrificial gates 120. In some embodiments, a gate dielectric film is formed of or includes silicon oxide. In some forms, the sacrificial gates are formed, for example, using polysilicon or amorphous silicon, and other materials may also be used.

Referring to FIG. 18A, gate spacers 126 are formed on the sidewalls of the sacrificial gates 120. Gate spacers can be formed of a low-k dielectric material such as silicon nitride, silicon carbo-nitride, or the like, and may have a single-layer structure or a multi-layer structure including a plurality of dielectric layers. FIG. 18A shows recesses 128 formed in parts of the fin 116 that are not covered by sacrificial gates 120 and gate spacers 126. The recesses are filled with source/drain structures 130. The source/drain structures 130 are formed on opposite sides of the sacrificial gate 120 at the channel region.

FIG. 18A shows an ILD layer 132 formed over the source/drain structures 130. CESLs 134 are provided in a region between the tops of the source/drain structures 130 and the ILD layers 132 and on the sidewalls of the ILD layers. An ILD layer and CESL can include or be formed of any material or combination of materials and may be formed by any process or combination of processes useful for forming an ILD layer or a CESL, such as any material, process, or combination thereof described herein in connection with ILD layer or a CESL. An interlayer 136 separates the CESL 134 from the gate spacers 126. The interlayer can include an insulator such as silicon nitride. A planarization process such as a CMP process or a mechanical grinding process may be performed to level the top surfaces of the ILD, the sacrificial gates, the gate spacers, the interlayer, and the CESL.

Referring to FIG. 18B, a Cut Poly process forms the gate cut openings 138 between the fins 116 and into the STI regions 118. The openings are filled with a sacrificial fin 140 protruding from the STI region 118. In some forms, a sacrificial fin can include an insulator such as silicon oxide or silicon nitride. A cut-poly refill dielectric 142 is formed over the sacrificial fins. In some forms, sacrificial fins and cut-poly dielectrics include an insulator such as a silicon nitride, silicon oxide, or high-k dielectric material. FIGS. 18A and 18B illustrate a layer 144 over the sacrificial gates 120, refill dielectric 142, and ILD layers 132. The layer 144 can serve as a hard mask and be formed of or include one or more materials such as silicon nitride, silicon oxynitride, silicon carbide, silicon carbon nitride, the like, or a combination thereof. In some forms, the layer is formed of SiN and has a thickness ranging from 600 Å to 890 Å. Following the formation of the SiN layer, the structure can be cleaned using a wet cleaning process such as a wet cleaning process as described herein.

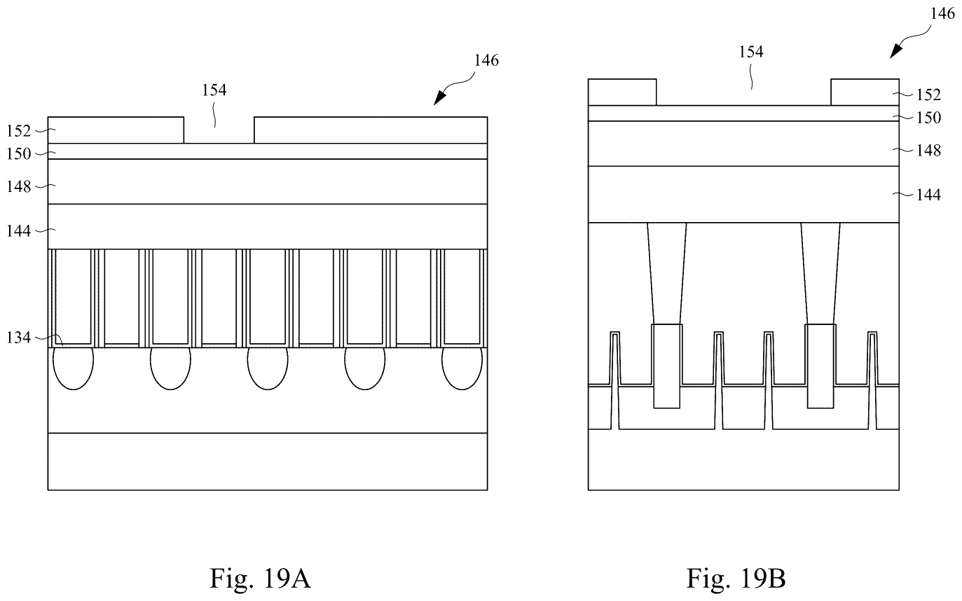

FIGS. 19A and 19B show a tri-layer mask 146 formed over the compressive layer 144. The tri-layer masking layer 146 includes a bottom layer 148, a middle layer 150 over the bottom layer, and an upper layer 152 including a photoresist disposed over the middle layer. In some forms, the upper layer has a thickness ranging from 300 Å to 500 Å, the middle layer has a thickness ranging from 150 Å to 350 Å, and the bottom layer has a thickness ranging from 700 Å to 900 Å. FIGS. 19A and 19B illustrate the upper layer 152 including an opening 154 formed by a photolithography process such as an EUV lithography process. The opening in FIGS. 19A and 19B is arranged at a location where a portion of sacrificial gate is to be cut with a CPODE process.

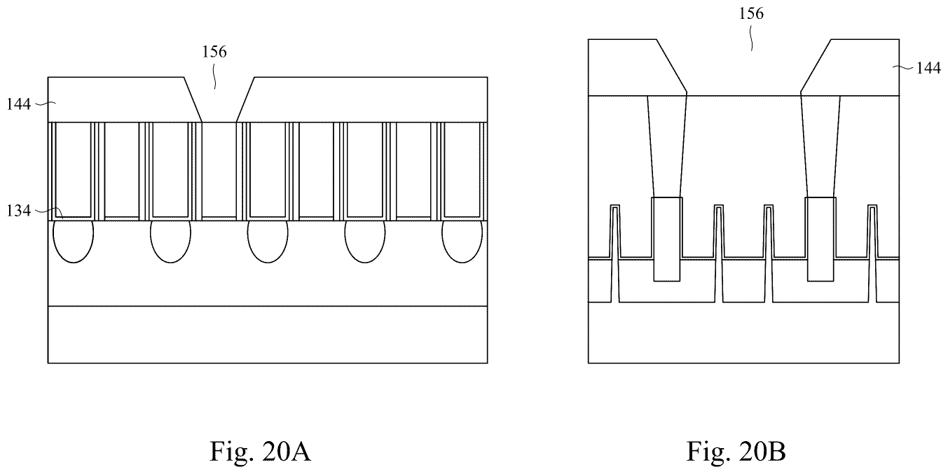

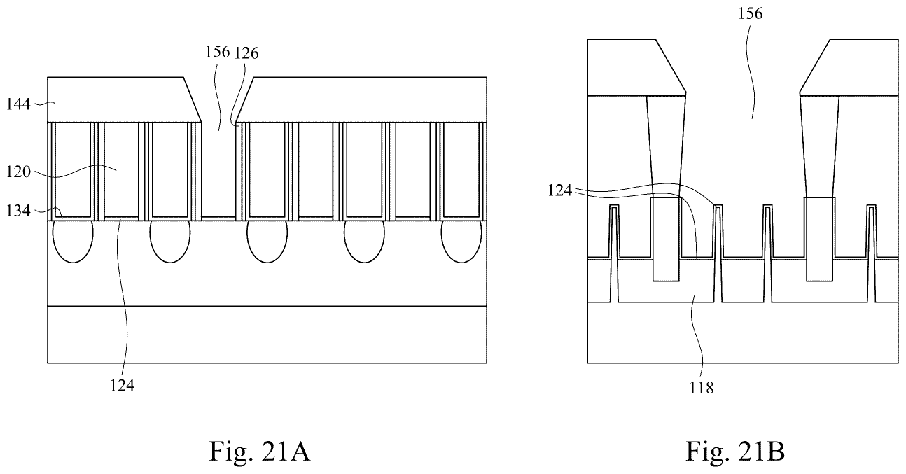

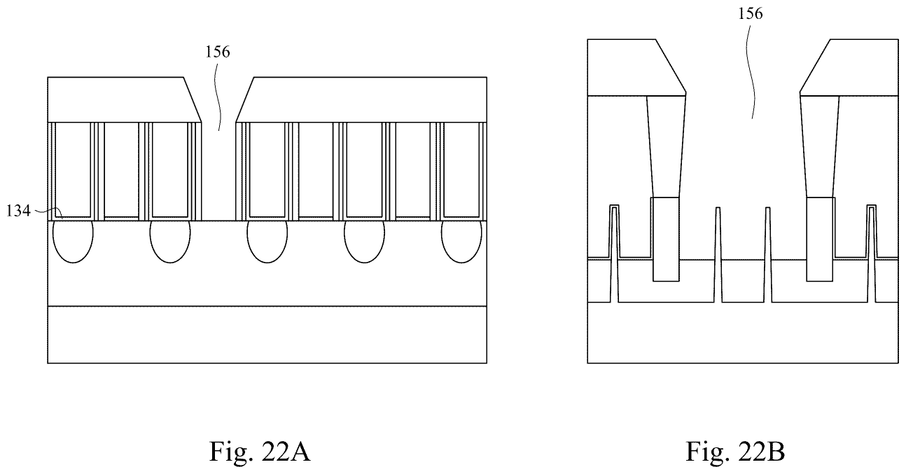

FIGS. 20A and 20B illustrate an embodiment of a structure upon forming an opening 156 a section of the compressive layer 144 using a first stage of a CPODE etching process. FIGS. 21A and 21B illustrate an embodiment of a structure upon removal of a portion of a sacrificial gate 120 under the opening 156 in the compressive layer using a second stage of a CPODE etching process. FIG. 21A illustrates that the second stage of the CPODE etching process exposes the gate dielectric 124 in a bottom of the opening and the gate spacers 126 on sidewalls of the opening. FIG. 21B shows that the opening 156 exposes the gate dielectric layer 124 formed over fins 116 and STI regions 118 in the bottom of the opening. FIGS. 22A and 22B illustrate an embodiment of a structure upon removal of the gate dielectric layer 124 from the opening during a third stage of a CPODE etching process.

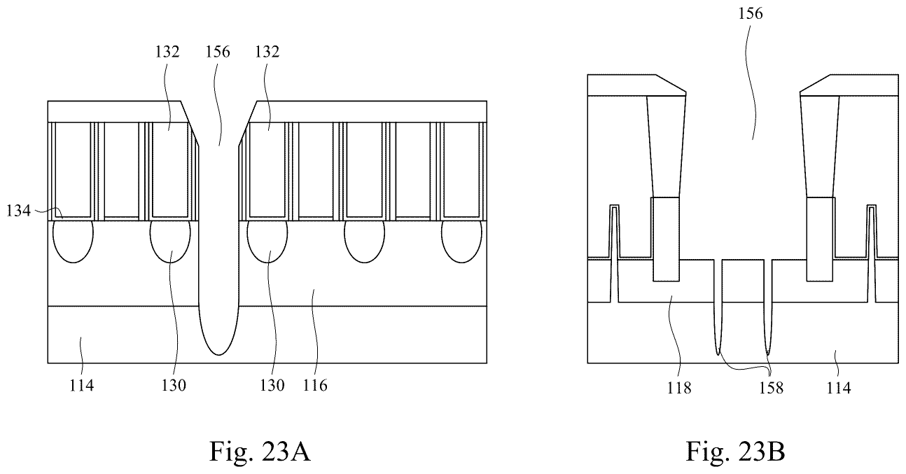

FIGS. 23A and 23B illustrate an embodiment of the structures of FIGS. 22A and 22B upon further etching to extend the opening 156 through a fourth stage of a CPODE etching process. FIG. 23A illustrates the opening 156 is formed through a portion of a fin 116 and into the substrate 114. FIG. 23B illustrates that the opening 156 is formed through portions of the STI regions 118 and into the substrate 114. The opening 156 extends into the substrate 114 to a depth below the source/drain structures 130 and below the STI regions 118. FIG. 23A illustrates the opening 156 dividing the fin along the first direction and not exposing the source/drain structures 130 or the ILD layers 132 along the first direction. FIG. 23B illustrates the opening 156 dividing the sacrificial gate 120 along the second direction. FIG. 23B also illustrates the bottom of the opening including plurality of trenches 158 separated in the second direction. Following any one or more of first, second, third and fourth stages of a CPODE etching process, resulting structures formed thereby can be cleaned before proceeding with further processing and the cleaning can use a wet cleaning process as described herein.

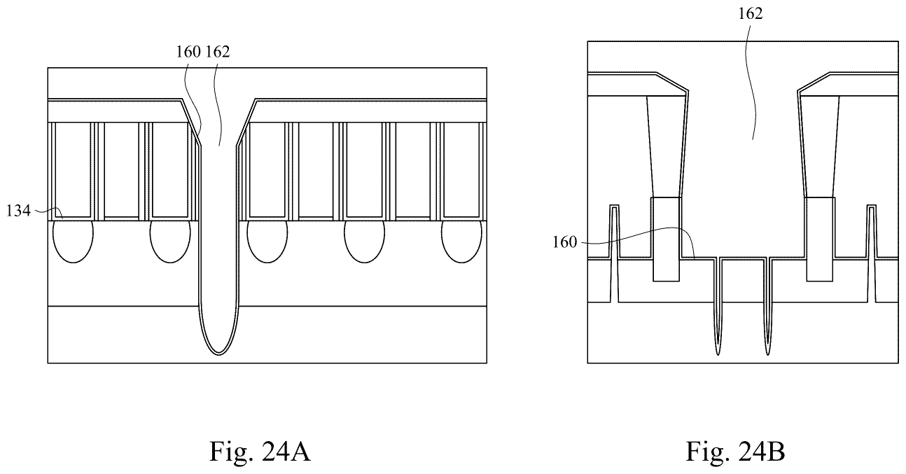

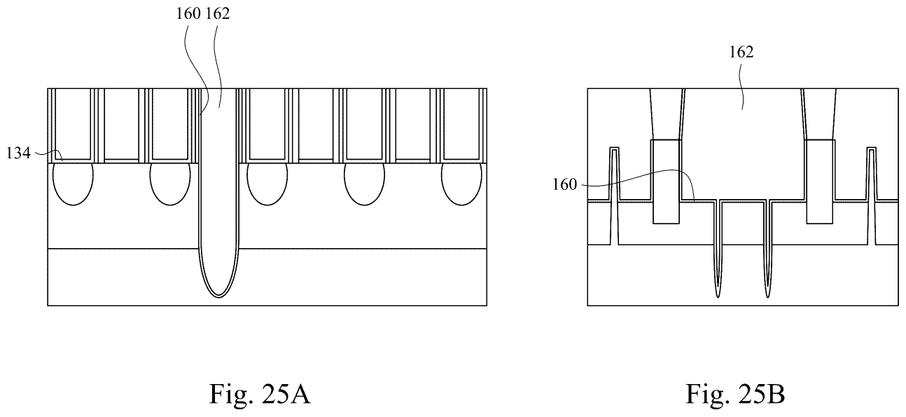

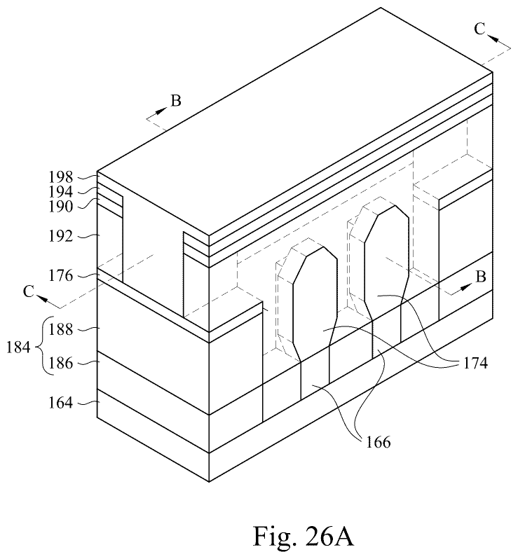

FIGS. 24A and 24B illustrate the structure of FIGS. 23A and 23B following deposition of a conformal dielectric liner 160 in the opening and deposition of a dielectric fill 162 over the liner 160. A conformal dielectric liner and a dielectric fill can include or be formed of any material or combination of materials and be formed by any process or combination of processes useful for respectively forming a conformal dielectric liner or a dielectric fill, such as any material, process, or combination thereof respectively described herein in connection with a conformal dielectric liner or a dielectric fill. FIGS. 25A and 25B illustrate the structure following planarization of the dielectric fill material using a process such as CMP.

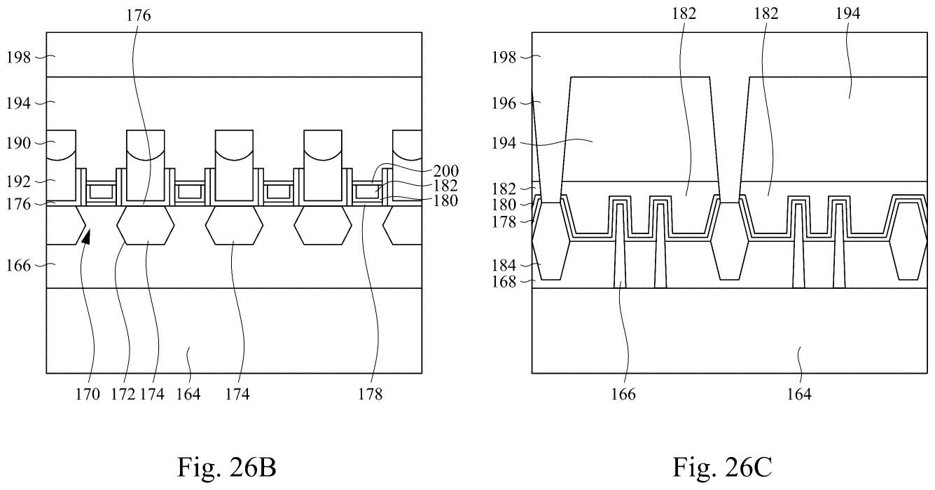

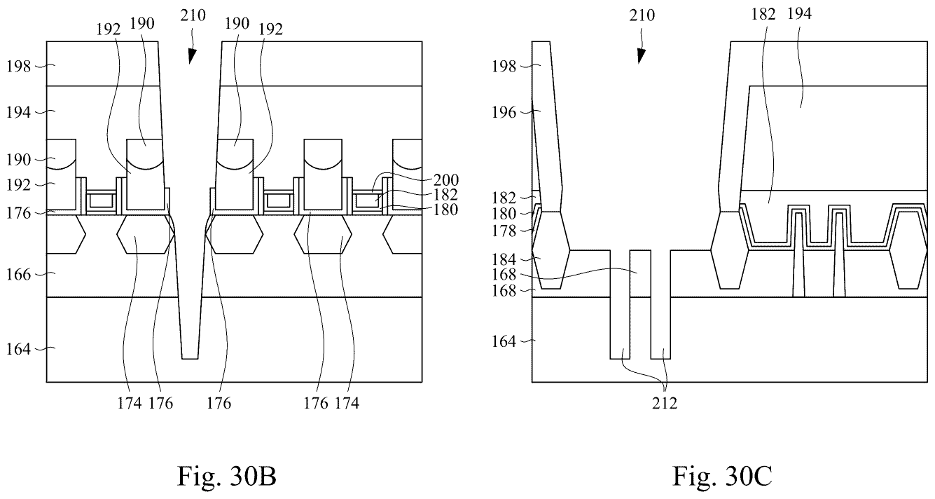

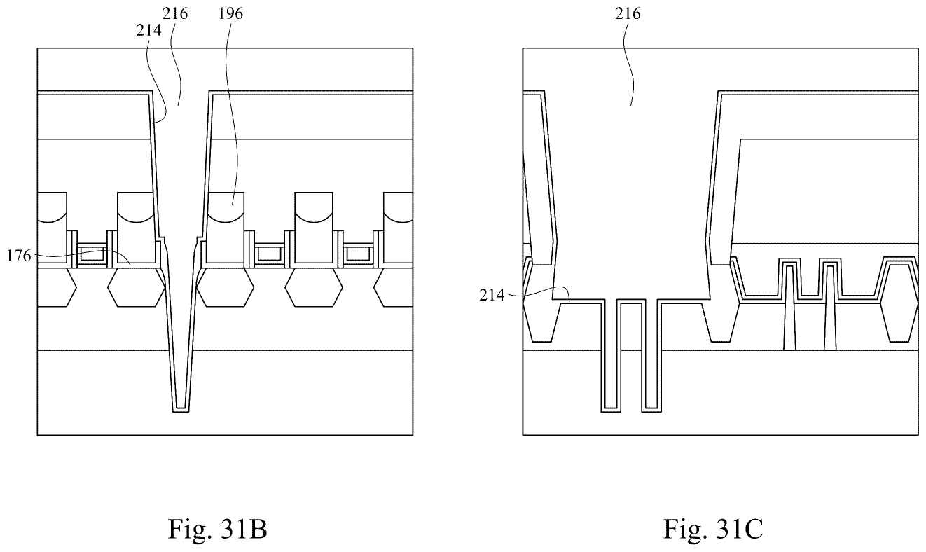

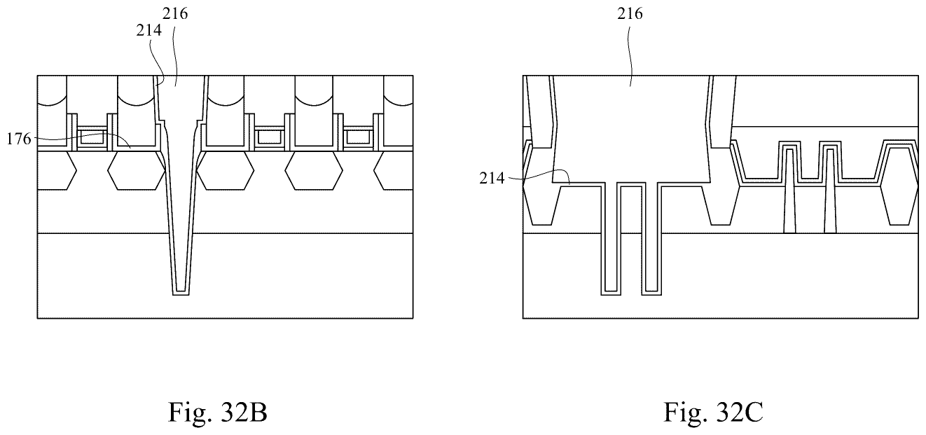

FIGS. 26A, 27A, 28A, 29A, and 30A illustrate perspective views of the structures at various stages of a method of manufacturing a semiconductor device including a plurality of Fin FET devices, according to some embodiments. FIGS. 26B, 27B, 28B, 29B, and 30B illustrate cross-sectional views of the structures respectively shown in FIGS. 26A, 27A, 28A, 29A, and 30A. Similarly, FIGS. 26C, 27C, 28C, 29C, and 30C are cross-sectional views of the structures respectively shown in FIGS. 26A, 27A, 28A, 29A, and 30A. FIG. 26A illustrates the locations of cross-sections B-B and C-C respectively along a first direction and a second direction. FIGS. 26B, 27B, 28B, 29B, and 30B ending with a “B” designation illustrate cross-sectional views at the various stages of processing corresponding to cross-section B-B shown in FIG. 26A. FIGS. 26C, 27C, 28C, 29C, and 30C ending with a “C” designation illustrate cross-sectional views at various instances of processing corresponding to cross-section C-C shown in FIG. 26A. FIGS. 31B and 32B show additional processing of the structure shown in FIG. 30B, according to some embodiments. FIGS. 31C and 32C show additional processing of the structure shown in FIG. 30C, according to some embodiments. In some figures, some reference numbers of components or features illustrated therein may be omitted to avoid obscuring other components or features, for ease of depicting the figures. FIGS. 26A, 26B, 26C, 27A, 27B, 27C, 28A, 28B, 28C, 29A, 29B, 29C, 30A, 30B, 30C, 31B, 31C, 32B, and 32C omit some structural features of the illustrated embodiment to simplify illustration and understanding.

As shown in FIGS. 26A-C, the structure includes a substrate 164, a plurality of fins 166 spaced apart on the substrate and extending in the first direction. STI regions 168 are disposed on the substrate with the fins 166 extending from the STI regions. The fins 166 include channel regions 170 and recesses 172 formed on opposite sides of the channel regions. Source/drain structures 174 are disposed in the recesses 172. CESLs 176 are formed over the source/drain structures 174, and an ILD layers 192 are formed on the CESLs 176. CESLs 176 are provided in a region between the tops of the source/drain structures 174 and the ILD layers 192 and on portions of the sidewalls of the ILD layers. The structure further includes interfacial dielectrics 178 formed on the fins 166, a gate dielectric layer 180 formed on the interfacial dielectrics 178, and plurality of metal gates 182 serving as gate electrodes extend in the second direction and are formed on a gate dielectric layer 180. The metal gates 182 are disposed over the substrate 164 and the STI regions 168. In some embodiments, the metal gate 182 is a work function metal. The metal gates 182 contact the channel regions 170 of the fins 166. In some embodiments, dielectric features 184 are formed between source/drain structures 174 and extend into the channel regions, as shown in FIGS. 26A and 26C. In some embodiments, each dielectric feature 184 includes a lower portion 186 and an upper portion 188. In some embodiments, the lower portion 186 and the upper portion 188 include different dielectric materials. For example, the lower portion 186 may include silicon nitride, and the upper portion 188 may include a high-k dielectric material. The dielectric feature 184 may include a different material or a different combination of materials and may have any suitable shape. The dielectric features 184 may be formed after forming the insulating material but prior to recessing the insulating material to form STI regions 168. For example, the openings are formed in the insulating material, and the dielectric features 184 are formed in the openings. The materials of the dielectric features 184 may be different from the STI regions 168.

FIGS. 26A and 26B show a hard mask 190 formed on the ILD layer 192. The hard mask 190 may include a dielectric material having different etch selectivity from the ILD layer 192. In some embodiments, the hard mask 190 includes silicon nitride. The hard mask 190 may be formed by recessing the ILD layer 192, forming the hard mask 190 in the recess, and performing a planarization process to expose the sacrificial gate stack prior to a replacement gate process. FIGS. 26A-26C illustrate a semiconductor layer 194 formed over the plurality of metal gate 182 and about the ILD layers 192 and hard mask layers 190. In some forms, a semiconductor layer is an SAC layer and may be formed of or include a semiconductor material such as amorphous silicon. In some embodiments, a conductive layer 200 is formed on the metal gate, and the layer including semiconductor material is formed on the conductive layer. The conductive layer may be a metal, such as a tungsten, for example fluorine-free tungsten.

FIGS. 26A and 26C illustrate a cut metal gate process to form gate cut structures that are filled with gate cut-fill structures 196. The cut metal gate process extend the gate cut structures through the semiconductor layer 194, the metal gate 182, the gate dielectric layer 180, and the interfacial dielectrics 178. The gate cut-fill structures 196 are in contact with corresponding dielectric feature 184, as shown in FIGS. 26A and 26C. FIGS. 26A-26C illustrate a structure after deposition of a hard mask 198 on the layer 194 and the gate cut-fill structures 196. In some forms, the hard mask 198 includes silicon nitride. In some embodiments, the hard mask 198 and the gate cut-fill structures 196 are monolithic. In other words, the hard mask 198 and the gate cut-fill structures 196 are formed at the same time by the same process and include the same material. In some embodiments, the hard mask 198 is a separate layer formed on the layer 194 and the gate cut-fill structures 196. The hard mask 198 may include a material different from the gate cut-fill structures 196. The hard mask 198 can have a thickness ranging from about 60 nm to about 80 nm. After the hard mask is formed, the structure can be cleaned using a wet cleaning process such as a wet cleaning process as described herein.

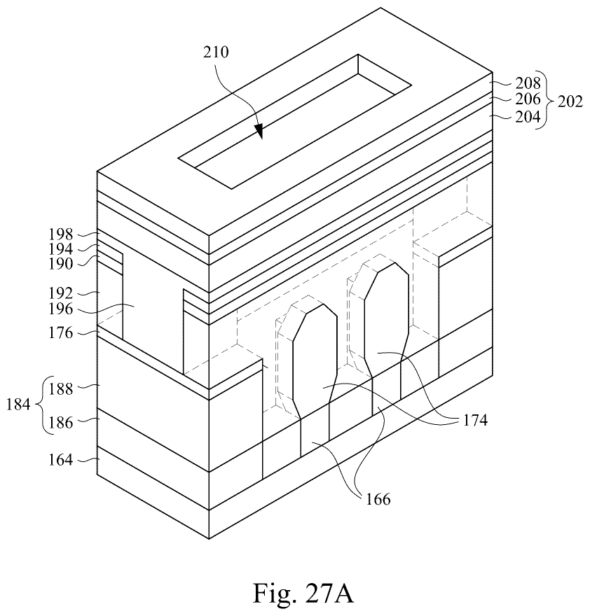

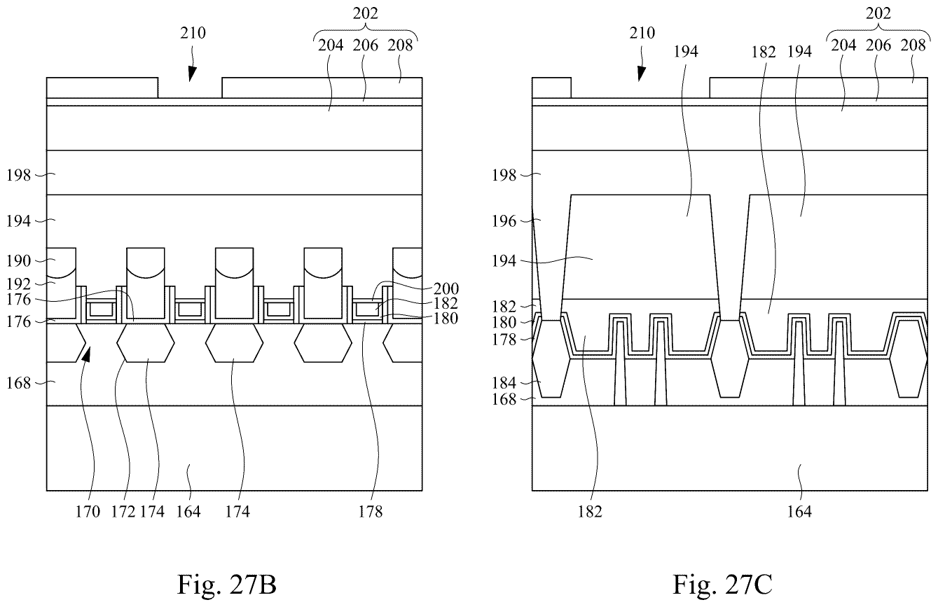

As shown in FIGS. 27A-C, a mask structure 202 is formed on the hard mask 198. In some embodiments, the mask structure 202 is a tri-layer photoresist. For example, the mask structure 202 may include a bottom layer 204, a middle layer 206 disposed on the bottom layer, and a photoresist layer 208 disposed on the middle layer. In some forms, the photoresist layer has a thickness ranging from 300 Å to 500 Å, the middle layer has a thickness ranging from 150 Å to 350 Å, and the bottom layer has a thickness ranging from 900 Å to 1100 Å. The bottom layer 204 and the middle layer 206 are made of different materials such that the optical properties and/or etching properties of the bottom layer and the middle layer are different from each other. In some embodiments, the bottom layer is a carbon-based layer, and the middle layer is a silicon-rich layer designed to provide an etch selectivity between the middle layer and the bottom layer. The photoresist layer 208 may be patterned using a photolithography process such as EUV photolithography, to form an opening 210. The opening 210 in FIGS. 27A-27C is arranged at a location where a portion of the metal gate 182 and layer 194 is to be removed with a CMODE process.

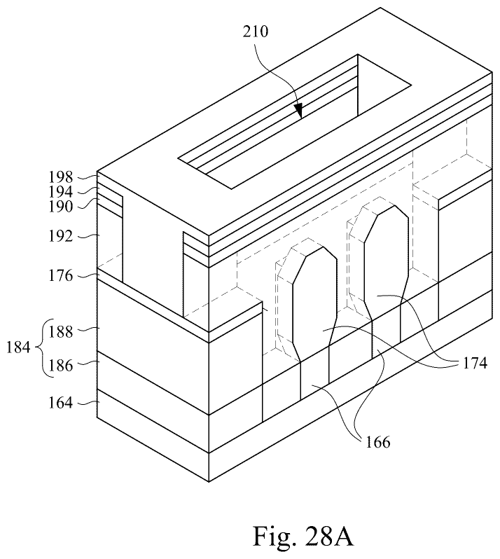

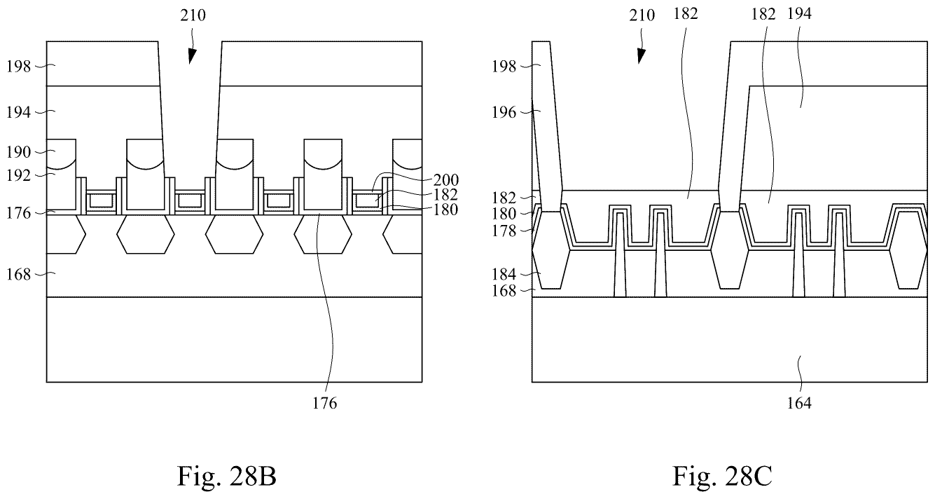

FIGS. 28A-C illustrate an embodiment of a structure upon extending the opening 210 using a first stage of a CMODE etching process using the mask structure 202 shown in FIGS. 27A-C. The first stage of the CMODE etching process can be a dry etch process. The mask structure may be removed after the opening 210 is extended to remove a section the layer 194, exposing the metal gate 182 in the opening 210. In some embodiments, a conductive layer and other gate cut-fill structures, as described above, are also removed. Following a first stage of the CMODE etching process, the resulting structure can be cleaned using a wet cleaning process such as a wet cleaning process as described herein.

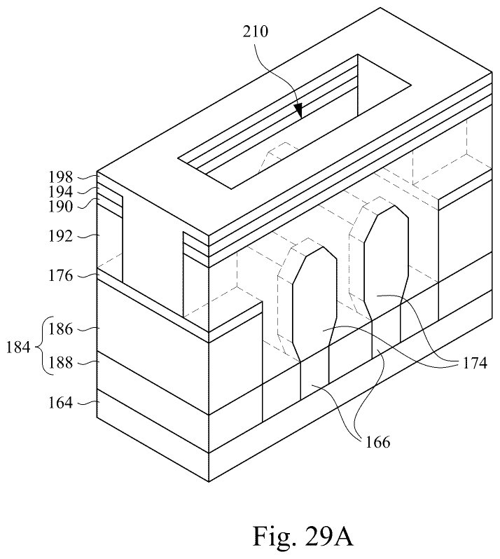

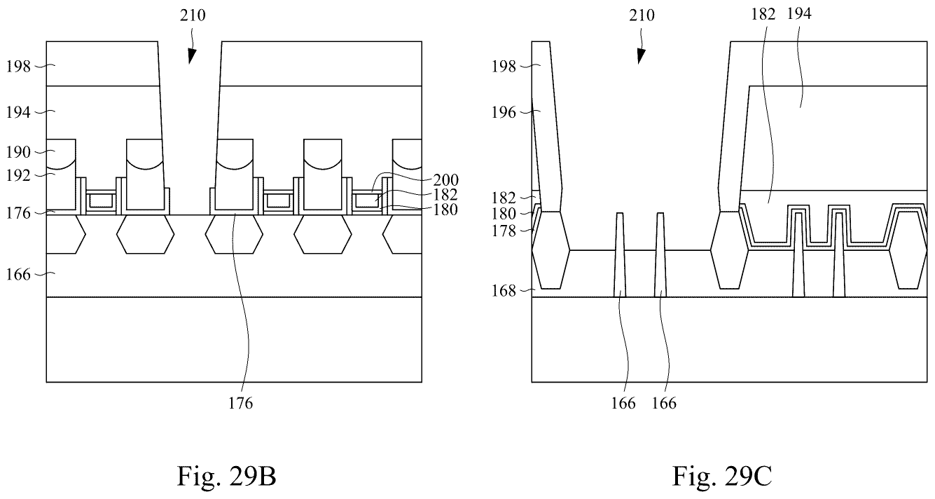

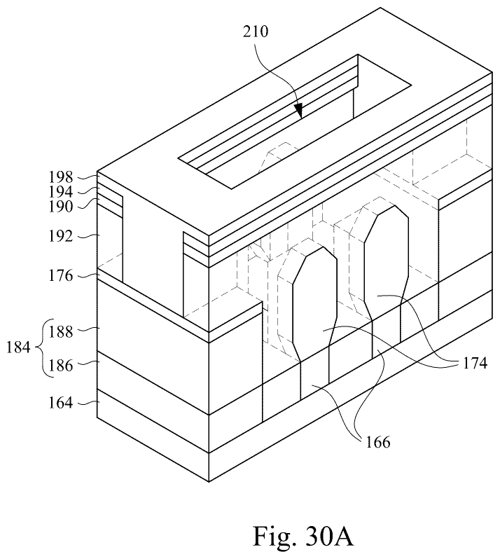

FIGS. 29A-C illustrate an embodiment of the structure upon extending the opening 210 to remove a section of the metal gate 182 in a second stage of a CMODE etching process. In some forms, the second stage of the CMODE etching process can be dry etch process. In other forms, a wet etch process can be used to produce the structure in FIGS. 29A-C. In some embodiments, portions of the gate dielectric layer 180 and the interfacial dielectrics 178 are also removed during a second stage of a CMODE etching process, and one or more fins 166 are exposed in the opening 210. Following a second stage of the CMODE etching process, the resulting structure can be cleaned using a wet cleaning process such as a wet cleaning process as described herein.

FIGS. 30A-C illustrate an embodiment of a structure upon removing exposed portions of the fins in the opening 210 (shown in FIG. 29C) and to extend the opening 210 through and below the STI regions 168 and into the substrate 164 using a third stage of a CMODE etching process. FIGS. 30B and 30C illustrate that the third stage of the CMODE etching process forms a plurality of trenches 212 in the bottom of the opening 210 and through the STI regions 168 and into the substrate 164. The trenches 212 are spaced apart along the second direction. FIG. 30B shows the opening 210 dividing a fin 166 of the plurality of fins between a pair of source/drain structures 174 along the first direction. FIG. 31B further illustrates that the opening 210 has a funnel profile, where a width of the funnel profile outside the substrate is greater than a width of the funnel profile within the substrate. In some embodiments, a portion of the CESL 176 (e.g., between 0 to 3 nm thick) remains on the sidewalls of the ILD layers 192 facing the opening 210. In some embodiments, a portion of the semiconductor layer 194 (e.g., ranging between 0 to 3 nm thick) remains on a surface of the CESL 176 layer facing the opening 210, in a region below the level of the hard mask layer 190. FIG. 30C illustrates the opening 210 dividing a metal gate 182 along the second direction. As shown in FIG. 30B, the opening 210 does not expose the pair of the source/drain structures 174, ILD layers 192, or hard mask 190 on either side of the opening along the first direction. As shown in FIG. 30C, the opening 210 does not expose the metal gate 182 on either side of the opening along the second direction. Gate cut structures filled with the gate-cut fill structure 196 space the opening 210 from the semiconductor layer 194 and the metal gate 182 along the second direction. In some forms, the third stage of the CMODE etching process includes a dry etch process. Following the third stage of the CMODE etching process, the resulting structure can be cleaned using a wet cleaning process such as a wet cleaning process as described herein.

FIGS. 31B and 31C are cross-sectional views showing the continued processing of the structures respectively shown in FIGS. 30A and 30C. A dielectric liner 214 is deposited and conformally lines the opening 210. The liner 214 can be or include silicon nitride, silicon oxide, silicon oxynitride, silicon carbon nitride, the like, or a combination thereof, and may be deposited by ALD, CVD, or another conformal deposition technique. In some embodiments, the liner 214 includes silicon oxide and is formed by flowing precursor gases, such as SiCl₄ and O₂, along with a carrier gas, such as Ar, into a processing chamber in which the structure is disposed therein. The flow rate of the SiCl₄ precursor may be less than about 100 sccm, the flow rate of the O₂ precursor may be less than about 100 sccm, and the flow rate of the carrier gas may range from about 50 sccm to about 500 sccm. A dielectric fill material 216 is deposited in the opening 210. The fill material 216 may be an insulating material. In some examples, fill material 216 may be a single insulating material, and in other examples, fill material 216 may include multiple different insulating materials, such as in a multi-layered configuration. The fill material 216 may include or be silicon oxide, silicon nitride, silicon oxynitride, silicon carbide, silicon carbon nitride, the like, or a combination thereof, and may be deposited by CVD, PVD, ALD, or another deposition technique. Following deposition of the fill material, the resulting structure can be cleaned using a wet cleaning process such as a wet cleaning process as described herein. FIGS. 32B and 32C show a structure obtained by planarizing the structure shown in FIGS. 31B and 31C by a process such as CMP.

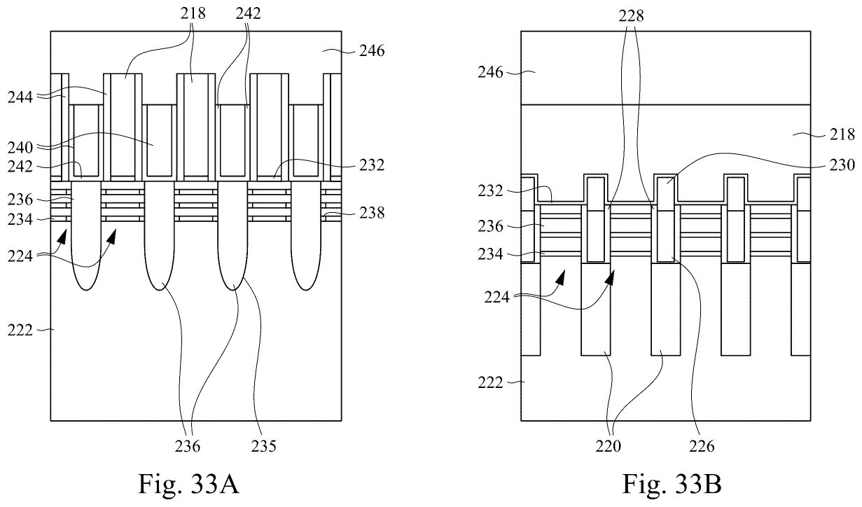

FIGS. 33A, 34A, 35A, 36A, 37A, 38A, and 39A illustrate cross-sections of sequential stages of a method of manufacturing a semiconductor device including a plurality of sheet FET devices, according to some embodiments. The cross-sections shown in FIGS. 33A, 34A, 35A, 36A, 37A, 38A, and 39A are taken along a sheet stack of the plurality of sheet FET devices, with the sheet stack extending in a first direction. FIGS. 33B, 34B, 35B, 36B, 37B, 38B, and 39B illustrate cross-sections taken along a sacrificial gate structure of the structures respectively shown in FIGS. 33A, 34A, 35A, 36A, 37A, 38A, and 39A, with the sacrificial gate extending in a second direction crossing the first direction.

FIGS. 33A through 37B illustrate a process of formation of an opening in a sheet stack and removal of a sacrificial gate 218. The opening electrically isolates neighboring sheet stack FETs. The opening can also be referred to as a CPODE region since the formation process involves the cutting of polysilicon sacrificial gate on the edge of active regions.

The structure illustrated in FIGS. 33A and 33B includes a substrate 222 including sheet stacks 224. FIG. 33B illustrates STI regions 220 about the bases of the sheet stacks 224. Dielectric layers 226 are formed over the STI regions 220. In some forms, the dielectric layers are formed of or include an insulating oxide such as silicon oxide, and may be formed through a deposition process, spin-on coating, or the like. Cladding layers 228 are formed on sides of the dielectric layers. In some forms, the cladding layers can include silicon-germanium. The cladding layers can be formed by a conformal deposition process such as ALD, CVD, or the like. A high-k dielectric region 230 is formed over the dielectric layer 226. In some forms, the high-k dielectric region can include hafnium oxide, zirconium oxide, aluminum oxide, aluminum nitride, titanium nitride, silicon oxide, silicon nitride, silicon oxynitride, silicon oxy-carbo-nitride, or the like. A conformal dielectric layer 232 is formed over the tops of the sheet stacks 224 and the high-k dielectric regions 230. In some forms, the conformal dielectric layer includes one or more layers of dielectric material, such as silicon oxide, silicon nitride, or a high-K dielectric.

As shown in FIGS. 33A and 33B, upper portions of the sheet stacks 224 include alternating first semiconductor layers 234 and second semiconductor layers 236. In some forms, the first semiconductor layers are formed of or include SiGe, Ge, Si, GaAs, InSb, GaSb, InAlAs, InGaAs, GaSbP, GaAsSb, combinations of these, or the like. In some aspects, the second semiconductor layers are formed of or include material such as Si, SiGe, Ge, GaAs, InSb, GaSb, InAlAs, InGaAs, GaSbP, GaAsSb, combinations of these, or the like. In some forms, the second layers include the same material as the substrate. In FIGS. 33A and 33B, the sheet stacks 224 further include a portion of the substrate 222 under the alternating first and second layers.

As shown in FIG. 33A, recesses 235 are formed between sheet stacks 224 and are filled with source/drain structures 237, which may be epitaxially grown. Inner spacers 238 are disposed between the source/drain structures 237 and the first semiconductor layers 234. In some forms, the inner spacers are formed of or include SiOCN, SiON, SiOC, SiCN, or the like. FIG. 33A illustrates ILD layers 240 over the source/drain structures. CESLs 242 are provided in a region between the tops of the source/drain structures 237 and the ILD layers 240 and on the sidewalls of the ILD layers. In some forms, the CESLs include silicon nitride.

FIGS. 33A and 33B illustrate sacrificial gates 218 formed over the tops of the sheet stacks 224. In some forms, the sacrificial gate includes polysilicon or amorphous silicon. FIG. 33A illustrates sacrificial gates 218 between source/drain structures 237. Low-k dielectric layers 244 form sidewalls on the sacrificial gates 218. FIGS. 33A and 33B illustrate a hard mask 246 deposited over the sacrificial gates 218, the CESLs 242, the ILD layers 240, the low-k dielectric spacers 244. In some forms, the hard mask is formed of or includes silicon nitride, silicon oxynitride, or the like. Following deposition of a hard mask, the resulting structure can be cleaned using a wet cleaning process such as a wet cleaning process as described herein.

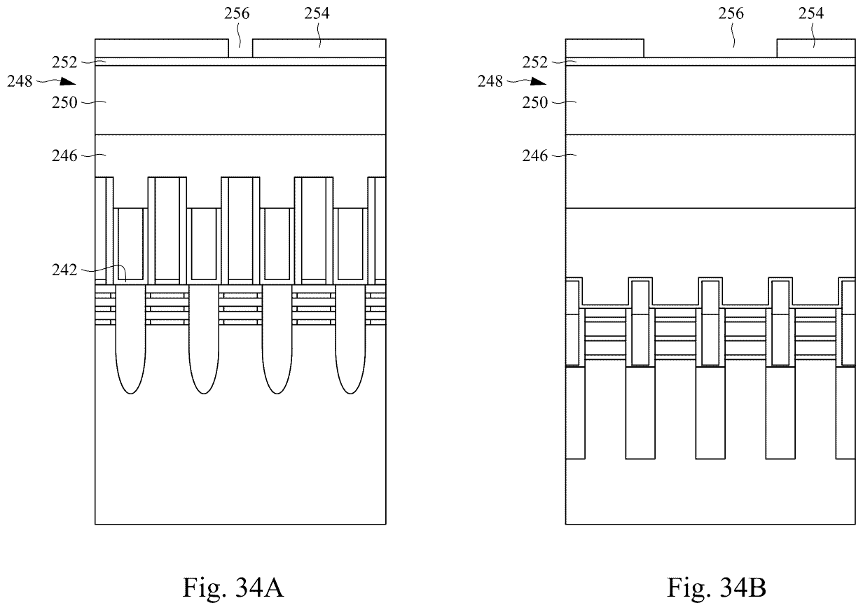

FIGS. 34A and 34B illustrate the structure following the deposition of a tri-layer masking layer 248 over the hard mask 246. The tri-layer masking layer 248 includes a bottom layer 250, a middle layer 252 over the bottom layer, and an upper layer 254 over the middle layer. In some forms, the upper layer is formed of a photoresist, the bottom layer is formed of a cross-linked photoresist, and the middle layer is formed of an inorganic dielectric material. An opening 256 is formed in the upper layer 254. The opening can be formed using a photolithography process such as EUV photolithography.

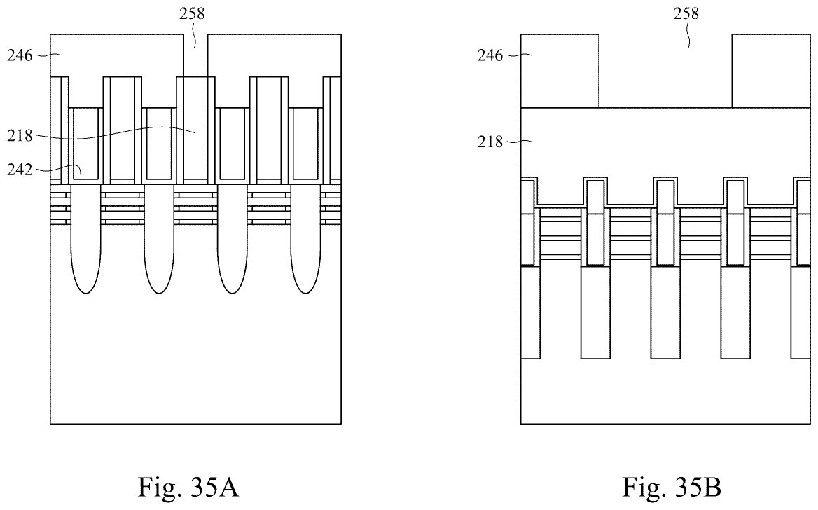

FIGS. 35A and 35B illustrate a structure obtained by performing a first stage of the CPODE etching process using the masking layer 246 as an etching mask. In some forms, the first stage of the CPODE process includes a dry etching process. In the illustrated embodiment, the first stage of CPODE process forms an opening 258 in the hard mask 246 and exposes the sacrificial gate 218 in a bottom of the opening. After obtaining the structure illustrated in FIGS. 35A and 35B, the structure can be cleaned using a wet cleaning process such as a wet cleaning process as described herein.

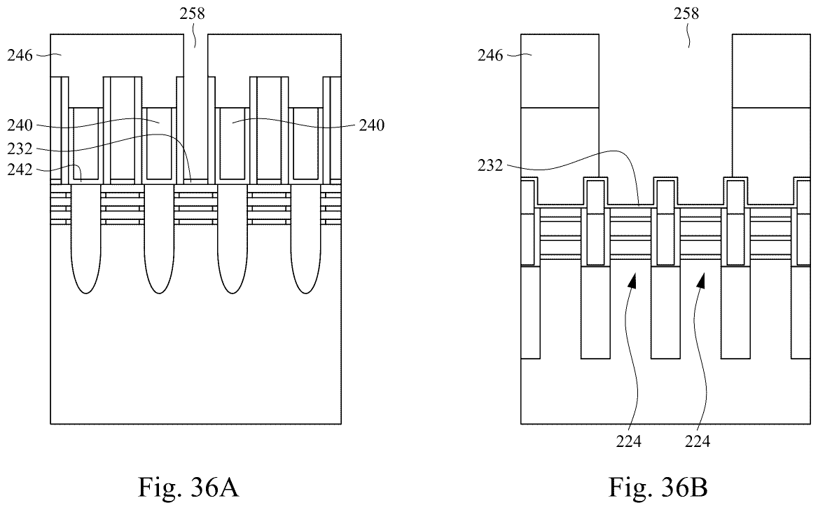

FIGS. 36A and 36B illustrate a structure obtained by conducting a second stage of a CPODE etching process using the hard mask 246 as an etching mask to extend the opening 258 to remove a sacrificial gate between ILD layers 240 and to expose the conformal dielectric layer 232. In some forms, the second stage of the CPODE etching process includes an anisotropic dry etching process retaining vertical sidewalls of the sacrificial gate 218, as illustrated in FIG. 36B. In the structure illustrated in FIGS. 36A and 36B, the opening 258 can be referred to as a through-gate trench. Sheet stacks 224 under the opening 258 illustrated in FIGS. 36A and 36B can be referred to as sacrificial sheet stacks. After obtaining the structure illustrated in FIGS. 36A and 36B, the structure can be cleaned using a wet cleaning process such as a wet cleaning process as described herein.

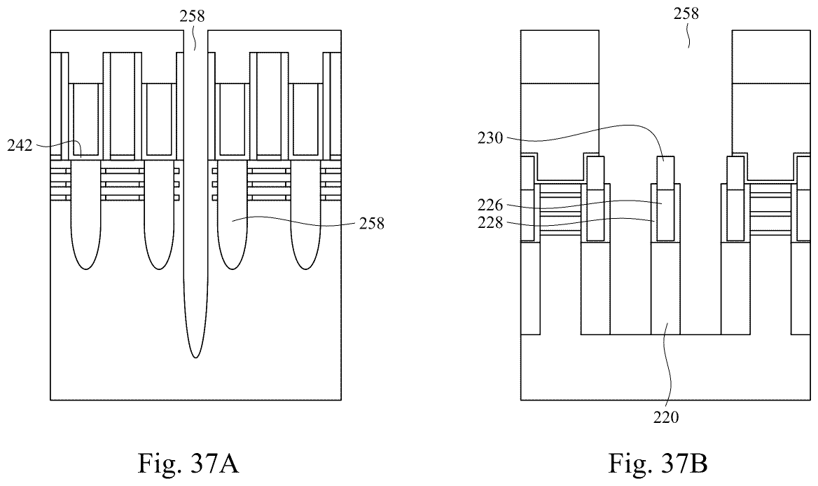

FIGS. 37A and 37B illustrate the structure obtained by conducting a third stage of a CPODE etching process to remove the conformal dielectric layer and the sacrificial sheet stacks shown in FIGS. 36A and 36B. The third stage of the CPODE etching process can be an anisotropic and selective dry etch process that retains the STI regions 220, the dielectric layers 226 formed over the STI regions, the cladding layers 228 formed on sides of the dielectric layers, and the high-k dielectric regions 230 formed over the dielectric layers. The opening 256 extends into the substrate and below the source/drain structures 237 in FIG. 37A and extends to the level of the bottom surface of STI regions 220 in FIG. 37B. In other forms, the trench extends below a level of a bottom of one or more STI regions. After obtaining the structure illustrated in FIGS. 37A and 37B, the structure can be cleaned using a wet cleaning process such as a wet cleaning process as described herein.

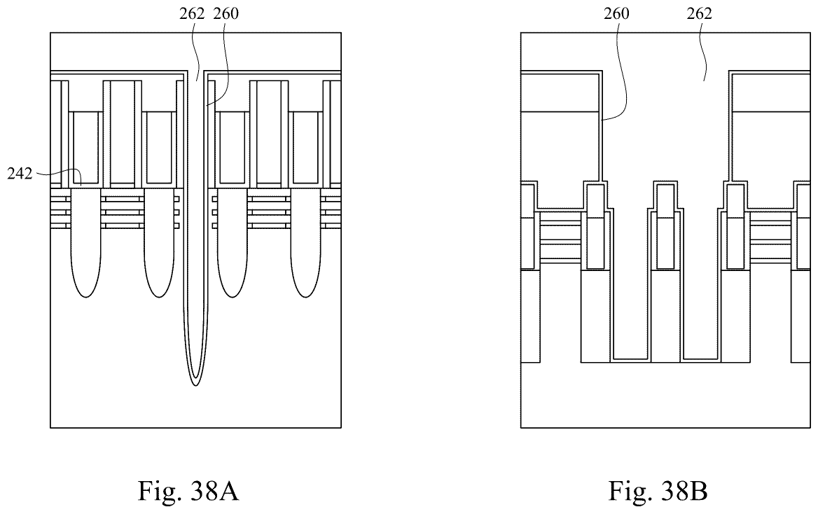

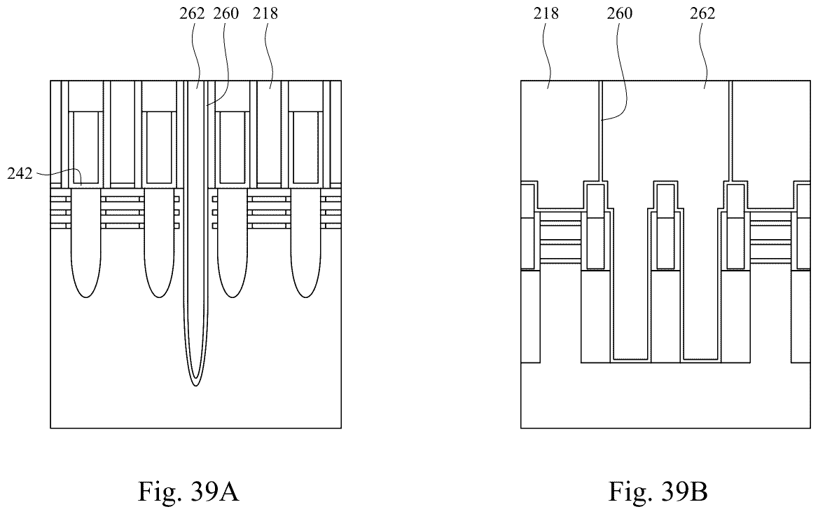

FIGS. 38A and 38B illustrate the structure following a deposition of dielectric materials in the opening 258 shown in FIGS. 37A and 37B. A dielectric liner layer 260 conforms to the bottom and sidewalls of the opening and a dielectric layer 262 fills the opening. In some forms, the dielectric liner is formed of or includes silicon oxide. In some aspects, the dielectric layer is formed of or includes silicon nitride. Other materials, such as SiC, SiON, SiCN, SiOCN, or the like may also be used to form one or more of the dielectric liner and dielectric layer. FIGS. 39A and 39B illustrate the structure following planarization of the surfaces of the sacrificial gates 218, the dielectric liner 260, dielectric layer 262, among other layers, using a CMP process.

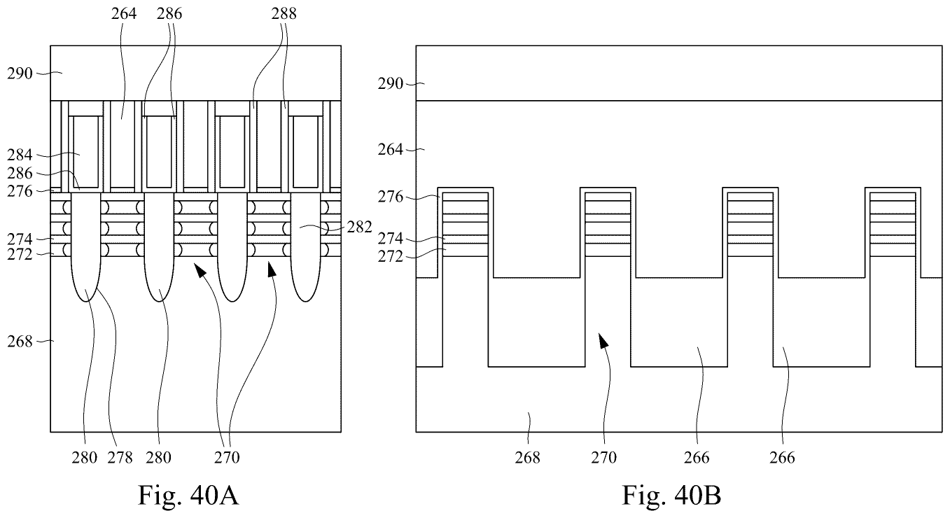

FIGS. 40A, 41A, 42A, 43A, 44A, and 45A, illustrate cross-sections of sequential stages of a method of manufacturing a semiconductor device including a plurality of sheet FET devices, according to some embodiments. The cross-sections shown in FIGS. 40A, 41A, 42A, 43A, 44A, and 45A are taken along a sheet stack of the plurality of sheet FET devices, with the sheet stack extending in a first direction. FIGS. 40B, 41B, 42B, 43B, 44B, and 45B illustrate cross-sections taken along a sacrificial gate structure of the structures respectively shown in 40A, 41A, 42A, 43A, 44A, and 45A, with the sacrificial gate extending in a second direction crossing the first direction.

FIGS. 40A through 45B illustrate a process of formation of an opening and removal of a sacrificial gate 264. The opening electrically isolates neighboring sheet stack FETs. The opening can also be referred to as a CPODE region since the formation process involves the cutting of sacrificial gate on the edge of active regions.

The structure illustrated in FIGS. 40A and 40B includes a substrate 268 and sheet stacks 270 formed over the substrate. FIG. 25B illustrates STI regions 266 formed about the sheet stacks and filled with one or more dielectric layers. Upper portions of the sheet stacks include alternating first layers 272 and second layers 274. First and second layers can include or be formed of any material or combination of materials and be formed by any process or combination of processes useful for forming the first and second layers, such as any material, process, or combination thereof described herein in connection with the first and second layers of a sheet stack. In some forms, the second layers include the same material as the substrate and the bases of the sheet stacks. FIGS. 40A and 40B further illustrate an interlayer oxide layer 276 conformally formed over the first layers 272 and second layers 274. In some forms, an interlayer oxide layer is formed of or includes silicon oxide, and may be formed through a deposition process, spin-on coating, or the like.

FIG. 40A illustrates recesses 278 formed between sheet stacks 270 and filled with source/drain structures 280. In some forms, the source/drain structures are epitaxially grown. Inner spacers 282 are disposed between the source/drain structures 280 and the first semiconductor layers 272. FIG. 40A illustrates ILD layers 284 formed over the source/drain structures 280. CESLs 286 are provided in a region between the tops of the source/drain structures 280 and the ILD layers 284 and on the sidewalls of the ILD layers. In some forms, the CESLs include silicon nitride. FIGS. 40A and 40B illustrate sacrificial gates 264 formed over the tops of the sheet stacks 270 and between the source/drain regions 280. In some forms, the sacrificial gate includes polysilicon or amorphous silicon. FIG. 40A illustrates gate sidewall spacers 288 formed on opposite sides of the sacrificial gates 264 and contacting the CESLs 286. Source/drain structures, ILDs, CESLs, gate sidewall spacers, and inner spacers can include or be formed of any material or combination of materials and be formed by any process or combination of processes useful for forming source/drain structures, ILDs, CESLs, gate sidewall spacers, or inner spacers, such as any material, process, or combination thereof described herein in connection with source/drain structures, ILDs, CESLs, gate sidewall spacers, or inner spacers.

FIGS. 40A and 40B illustrate a hard mask 290 deposited over the sacrificial gates 264, the CESLs 286, and the sidewall spacers 288. The hard mask can include or be formed of any material or combination of materials and be formed by any process or combination of processes useful for forming a hard mask, such as any material, process, or combination thereof described herein in connection with a hard mask. Following deposition of the hard mask, the resulting structure can be cleaned using a wet cleaning process such as a wet cleaning process as described herein.

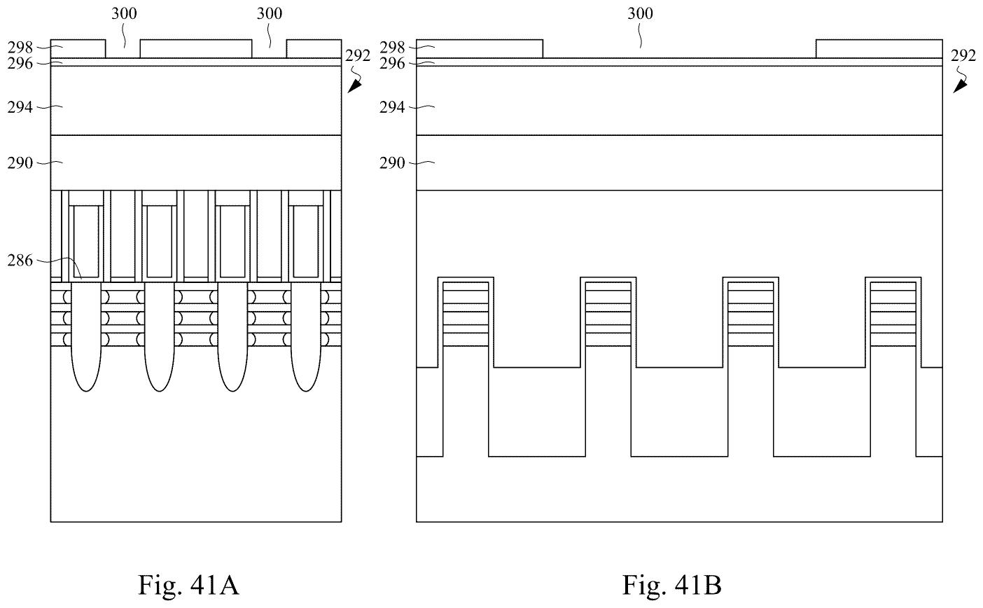

FIGS. 41A and 41B illustrate the structure following deposition of a tri-layer masking layer 292 over the hard mask 290. The tri-layer masking layer 292 includes a bottom layer 294, a middle layer 296 over the bottom layer, and an upper layer 298 over the middle layer. An opening 300 is formed in the upper layer 298 of the masking layer and extends across an area corresponding to plural sheet stacks 270, as shown in the cross-section of FIG. 41B. The opening can be formed using a photolithography process, such as EUV photolithography.

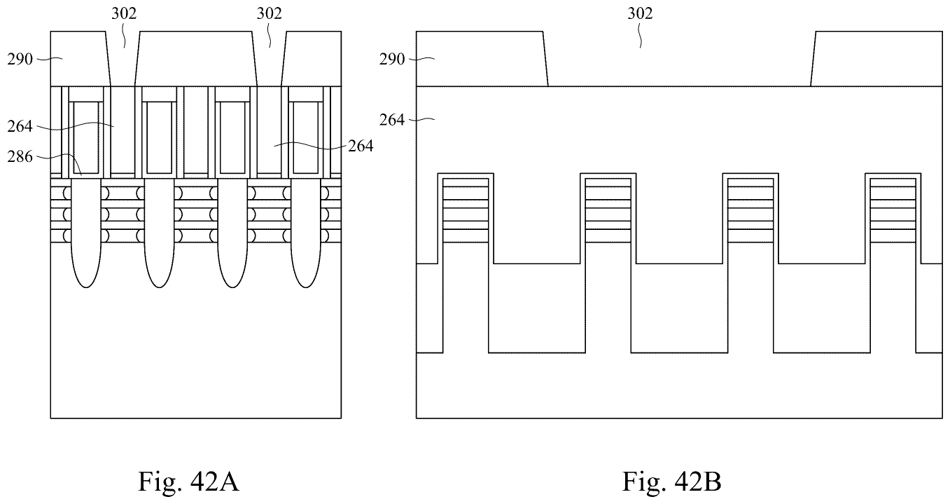

FIGS. 42A and 42B illustrate the structure obtained by performing a first stage of a CPODE etching process using the masking layer 292 in FIGS. 41A and 41B as an etching mask. In some forms, the first stage of the CPODE process includes a dry etching process. In the illustrated embodiment, the first stage of CPODE process forms an opening 302 in the hard mask 290 and exposes the sacrificial gate 264 in a bottom of the opening 302. After obtaining the structure illustrated in FIGS. 42A and 42B, the structure can be cleaned using a wet cleaning process such as a wet cleaning process as described herein.

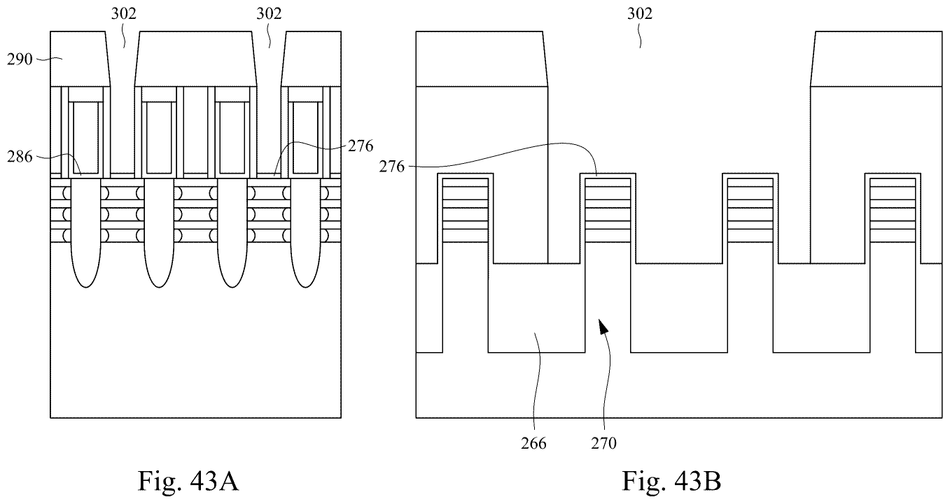

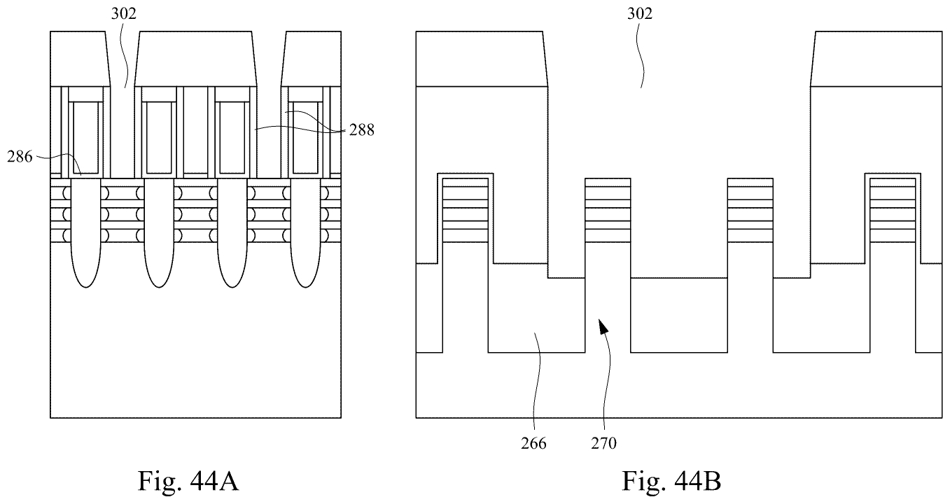

FIGS. 43A and 43B illustrate the structure obtained by conducting a second stage of a CPODE etching process using the hard mask 290 as an etching mask to extend the opening 302 through the sacrificial gate 264 between ILD layers 284 to expose the conformal oxide layer 276. In the structure illustrated in FIG. 43B, top portions of the sheet stacks protrude from the STI regions 266 and are covered with the conformal oxide layer 276. In some forms, the second stage of the CPODE process includes a dry etching process. After obtaining the structure illustrated in FIGS. 43A and 43B, the structure can be cleaned using a wet cleaning process such as a wet cleaning process as described herein.

FIGS. 44A and 44B illustrate the structure obtained by conducting a third stage of a CPODE etching process to remove the interlayer oxide layer 276 shown in FIGS. 43A and 43B. The third stage of the CPODE etching process can be a selective dry etch process that retains the STI regions 266, the sheet stacks 270, and the sidewall spacers 288. After obtaining the structure illustrated in FIGS. 44A and 44B, the structure can be cleaned using a wet cleaning process such as a wet cleaning process as described herein.

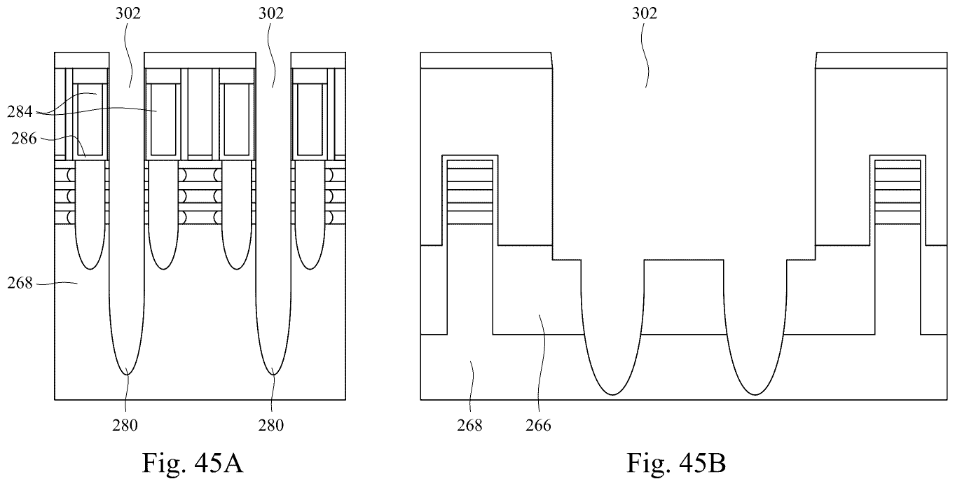

FIGS. 45A and 45B illustrate the structure obtained by conducting a fourth stage of a CPODE etching process to remove sheet stacks exposed in the opening shown in FIGS. 44A and 44B to extend the opening 302 into the substrate 268 and below the source/drain structures 280 in FIG. 45A and below the STI regions 266 in FIG. 45B. The CPODE etching process does not expose the source/drain structures 280 or the ILD layers 284. After obtaining the structure illustrated in FIGS. 45A and 45B, the structure can be cleaned using a wet cleaning process such as a wet cleaning process as described herein. The opening 302 in the structure illustrated in FIGS. 45A and 45B can be filled with one or more dielectric materials, as provided herein.

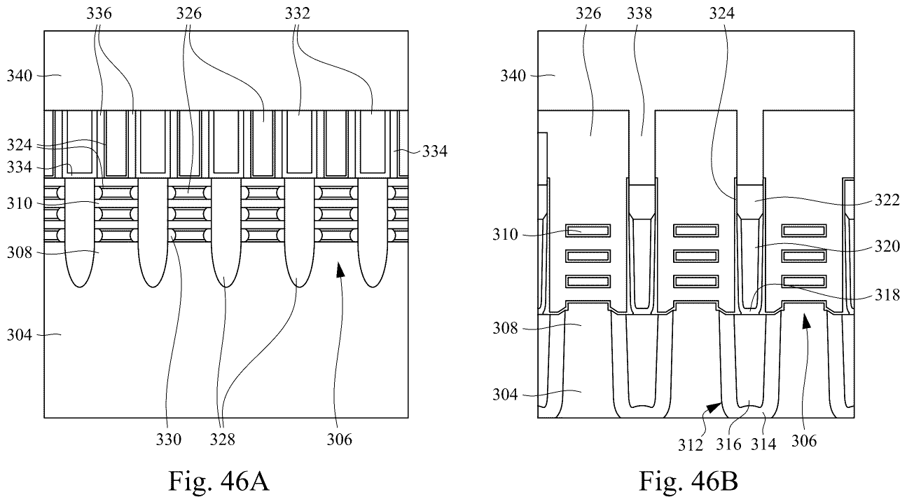

FIGS. 46A, 47A, 48A, 49A, 50A, 51A, and 52A illustrate cross-sections of sequential stages of a method of manufacturing a semiconductor device including a plurality of sheet FET devices, according to some embodiments. The cross-sections shown in FIGS. 46A, 47A, 48A, 49A, 50A, 51A, and 52A are taken along a sheet stack of the plurality of sheet FET devices, with the sheet stack extending in a first direction. FIGS. 46B, 47B, 48B, 49B, 50B, 51B, and 52B illustrate cross-sections taken along a metal gate structure of the structures respectively shown in FIGS. 46A, 47A, 48A, 49A, 50A, 51A, and 52A, with the metal gate structure extending in a second direction crossing the first direction.

FIGS. 46A and 46B illustrate cross-sections of the structure with sheet stacks 306 formed over the substrate 304. The sheet stacks include bases 308 and a plurality of sheets 310 disposed above the bases. In some forms, the sheets have the same composition as the substrate. STI regions 312 are formed about bases 308 of stacks 306. The STI regions include a first dielectric layer 314 conformally deposited in recesses about the bases, and a second dielectric layer 316 formed over the first layer 314. STI regions, including first and second dielectric layers, sheets, and a substrate can include or be formed of any material or combination of materials and be formed by any process or combination of processes useful for forming substrates, sheets, or STI regions, such as any material, process, or combination thereof described herein in connection with substrates, sheets, or STI regions.

FIG. 46B further illustrates a conformal semiconductor layer 318 deposited in a trench over the STI regions 312. In some forms, the conformal semiconductor layer is formed of or includes a semiconductor material, such as silicon-germanium, and is formed using a process, such as ALD, CVD, or the like. A dielectric layer 320 is formed over the conformal layer 318. In some forms, the dielectric layer is formed of or includes an insulating oxide such as silicon oxide, and may be formed through a deposition process, spin-on coating, or the like. A high-k dielectric layer 322 is formed over the dielectric layer 320. A gate dielectric layer 324 is formed over the tops of the sheet stacks 306, around the sheets 310, and sides of the conformal layer 318 and the high-k dielectric layer 322. A high-k dielectric layer and a gate dielectric layer can include or be formed of any material or combination of materials and can be formed by any process or combination of processes useful for forming a high-k dielectric or a gate dielectric layer, such as any material, process, or combination thereof respectively described herein in connection with a high-k dielectric or a gate dielectric layer.

FIGS. 46A and 46B illustrate metal gates 326 formed over the stacks 306 and around gate dielectric layer 324 and sheets 310 within the channel regions. The metal gate includes or is formed of any material or combination of materials and may be formed by any process or combination of processes useful for forming a metal gate, such as any material, process, or combination thereof described herein in connection with a metal gate.

FIG. 46A illustrates source/drain structures 328 between the stacks 306 and at opposite sides of the sheets 310, with portions of the metal gate 326 between the sheets. FIG. 46A further illustrates inner spacers 330 disposed between the source/drain structures 328 and regions of the metal gate 326 between the sheets 310. A source/drain structure and an inner spacer can include or be formed of any material or combination of materials and can be formed by any process or combination of processes useful for forming a source/drain structure or an inner spacer, such as any material, process, or combination thereof described herein in connection with a source/drain structure or an inner spacer.

FIG. 46A further illustrates ILD layers 332 formed over the source/drain structures 328. CESLs 334 are provided in a region between the tops of the source/drain structures 328 and the ILD layers 332 and on the sidewalls of the ILD layers. In some forms, the CESLs include silicon nitride. Opposite sides of the metal gate in FIG. 46A are further covered with a gate sidewall spacer 336. The ILD layer, CESL, and gate sidewall spacer can include or be formed of any material or combination of materials and be formed by any process or combination of processes useful for respectively forming an ILD layer, a CESL, or a gate sidewall spacer, such as any material, process, or combination thereof respectively described herein in connection with a ILD layer, a CESL, or a gate sidewall.

FIG. 46B illustrates the after performing a Cut Metal Gate process to form gate isolation cuts 338 through the metal gate 326 and to expose the high-k dielectric layer 322 formed over the STI regions 312. The sheet stacks between the isolation cuts becomes a sacrificial stack following the formation of the cuts. FIG. 46A illustrates a hard mask layer 340 formed over the metal gates 326, the CESLs 334, the ILD layers 332, and the gate sidewall spacers 336. FIG. 46B illustrates the hard mask layer 340 formed over metal gate 326 and filling the gate isolation cuts 338. The hard mask layer can include or be formed of any material or combination of materials and be formed by any process or combination of processes useful for forming a hard mask layer, such as any material, process, or combination thereof described herein in connection with a hard mask layer. After the hard mask is formed, the structure can be cleaned using a wet cleaning process such as a wet cleaning process as described herein.

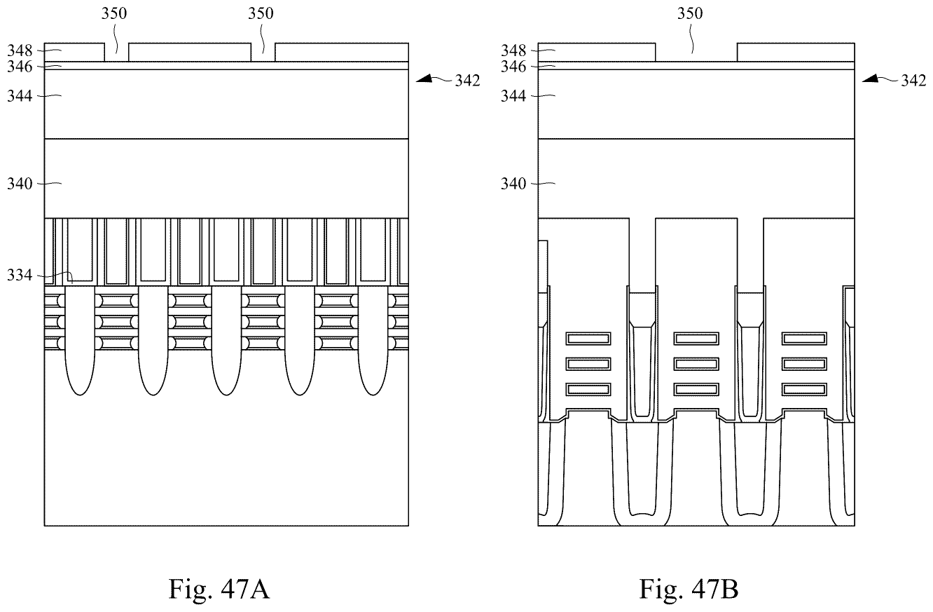

FIGS. 47A and 47B illustrate the structures respectively shown in FIGS. 46A and 46B following formation of a tri-layer masking layer 342 over the hard mask 340. The tri-layer masking layer includes a bottom layer 344, a middle layer 346 over the bottom layer, and an upper layer 348 over the middle layer. In some forms, the upper layer includes a photoresist, the middle layer includes an oxide such as silicon oxide, and the bottom layer includes a carbon-based layer. Any useful masking layer can be applied to the structure shown in FIGS. 47A and 47B. The masking layer can include or be formed of any material or combination of materials and be formed by any process or combination of processes useful for forming a masking layer, such as any material, process, or combination thereof described herein in connection with a masking layer. FIGS. 47A and 47B illustrate the upper layer 348 including the photoresist after patterning to form openings 350. The upper layer can be patterned using any suitable photolithography process described herein to form one or more openings therein. The openings in FIGS. 47A and 47B are arranged at locations where the metal gate 326 is to be cut with a CMODE process.

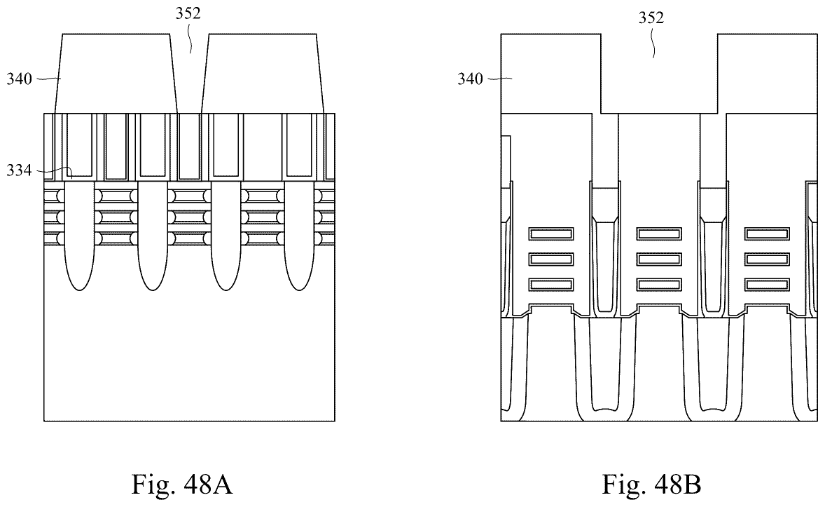

FIGS. 48A and 48B illustrate an embodiment of the structure of a semiconductor device upon removal of a section of the hard mask 340 by a first stage of a CMODE etching process using the masking layer to form openings 352 in the hard mask 340. In some forms, the first stage of the CMODE process is a dry etch process. Following the first stage of the CMODE process, the structure can be cleaned using a wet cleaning process such as a wet cleaning process as described herein.

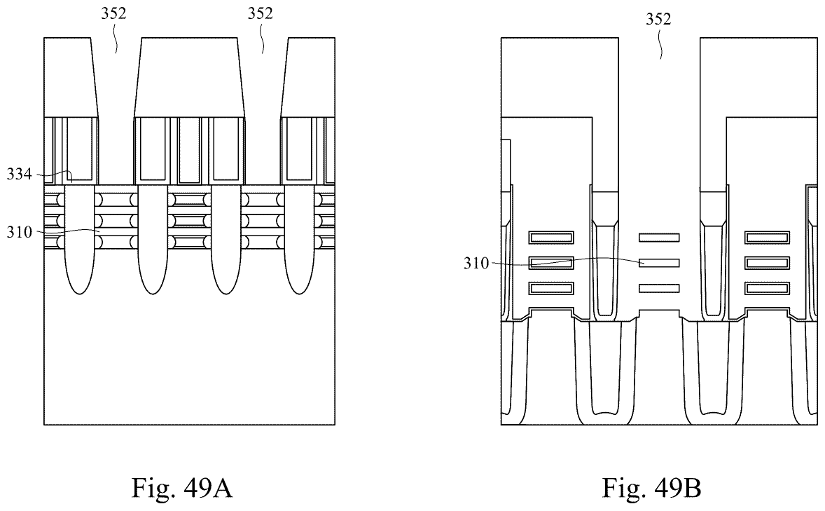

FIGS. 49A and 49B illustrate the structure following the second stage of a CMODE etching process to extend the openings 352 and remove sections of the metal gate 326 and gate dielectric layer 324. The second stage of the CMODE etching process removes the metal gate and gate dielectric layer from between the sheets 310. The second stage of the CMODE etching process can include a dry etch. In an alternate form, the structure is obtained by a wet etch process. The structure in FIGS. 49A and 49B can be cleaned using a wet cleaning process such as a wet cleaning process as described herein.

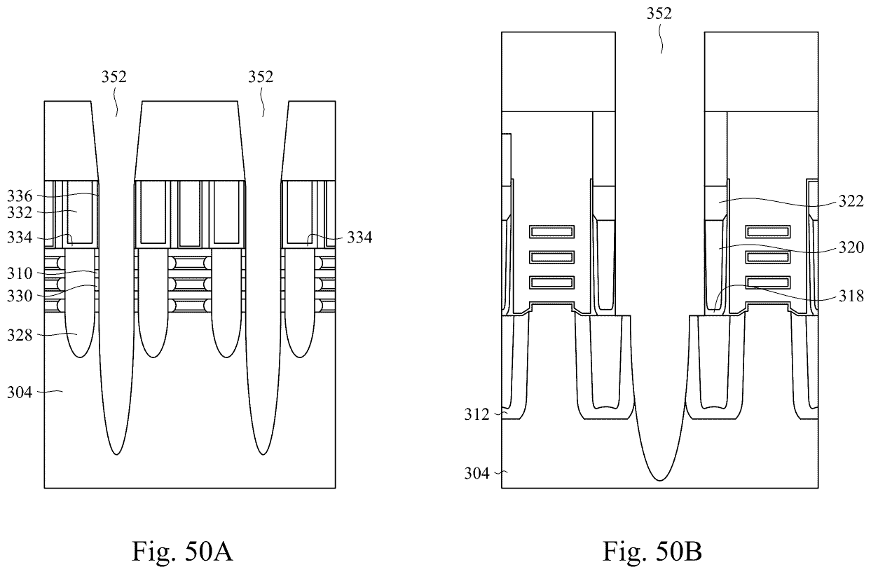

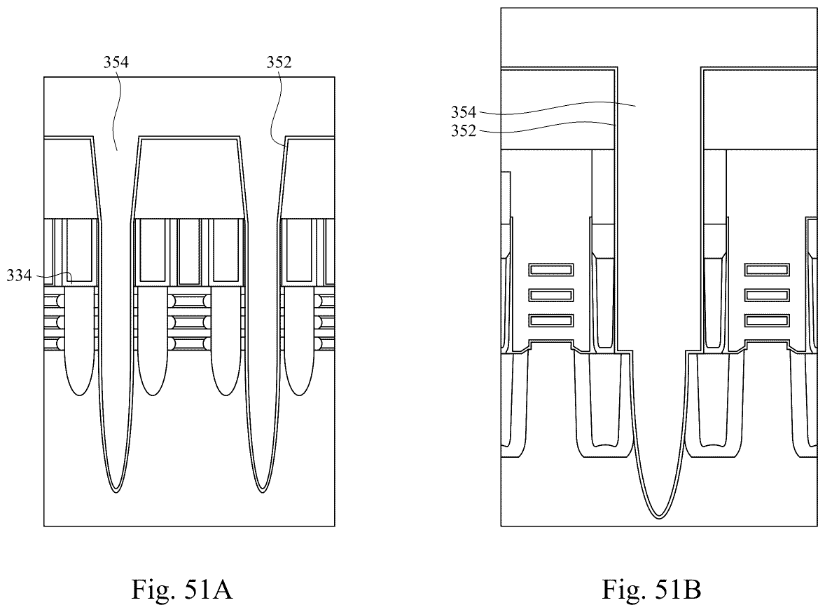

FIGS. 50A and 50B illustrate the structure after performing a third stage of a CMODE process on the structure shown in FIGS. 49A and 49B to extend the openings 352 into the substrate 304. The openings 352 extend below the source/drain structures 328 and the STI regions 312 and into the substrate 304. The third stage of the CMODE process can include a directional anisotropic dry etch process. As illustrated in FIG. 50A, the third stage of the CMODE process retains at least portions of the inner spacers 330 with portions of sheets 310 therebetween, and the opening 352 does not expose the source/drain structures 328. Also, the opening 352 does not expose the ILD layers 332 and CESL 334 and retains at least a portion of the gate sidewall spacer 336 lining walls of the opening 352. In FIG. 50B, the third stage of the CMODE process extends the opening 352 to remove portions of the substrate 304 positioned beneath a slot defined by the hard mask 340 while avoiding damage to the conformal semiconductor layer 318, the dielectric layer 320, and the high-K dielectric layer 322. Following the third stage of the CMODE etching process, the structure can be cleaned using a wet cleaning process such as a wet cleaning process as described herein.

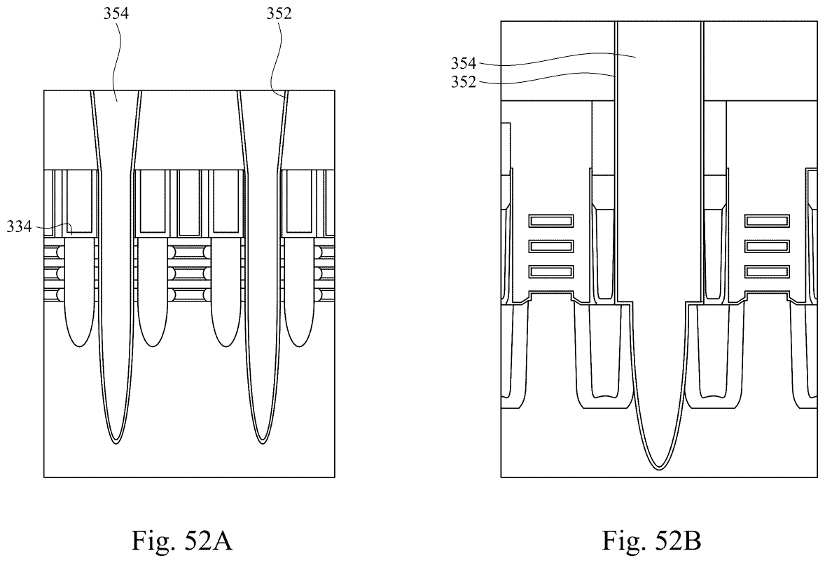

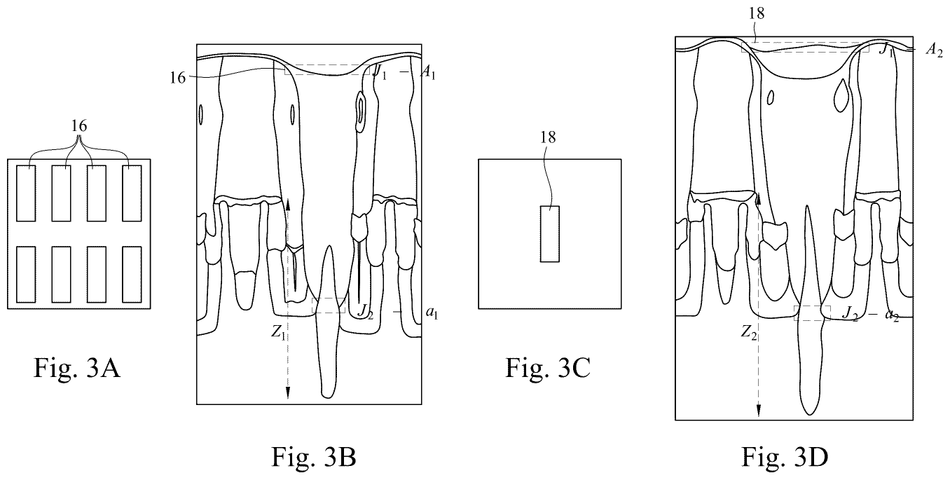

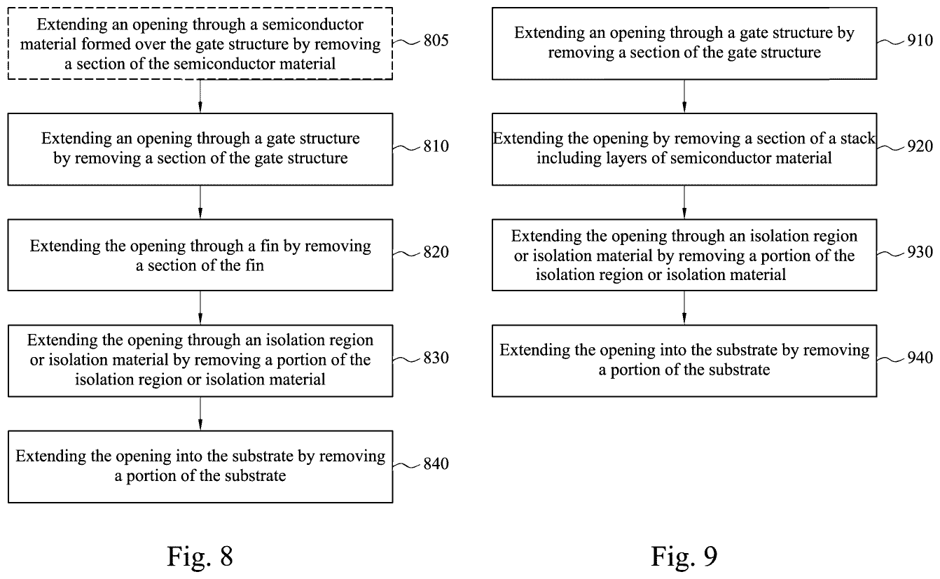

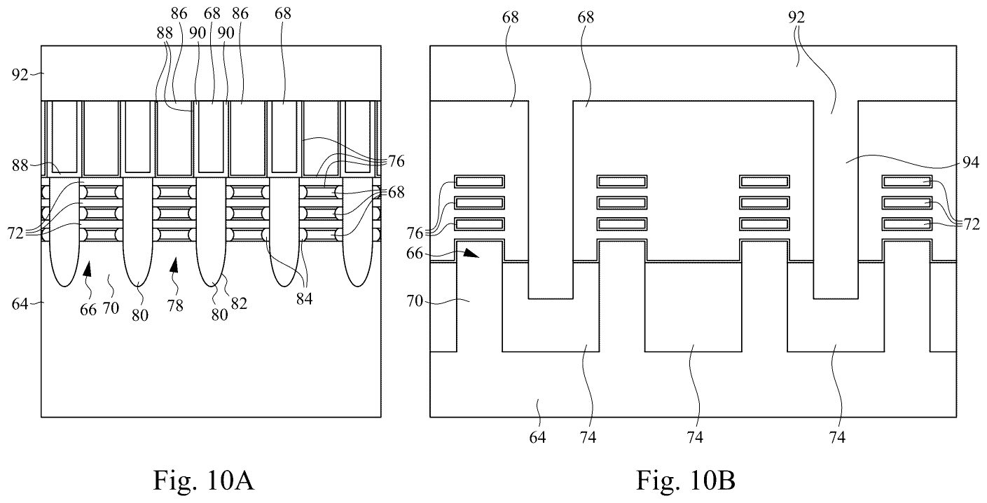

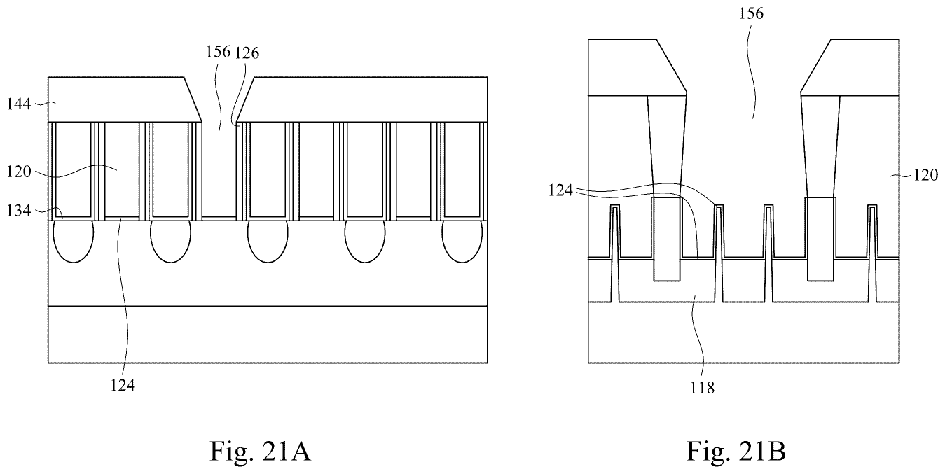

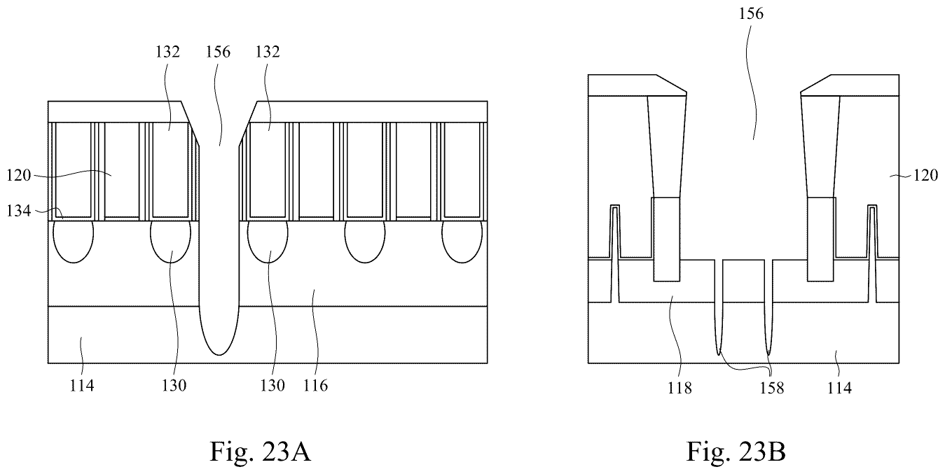

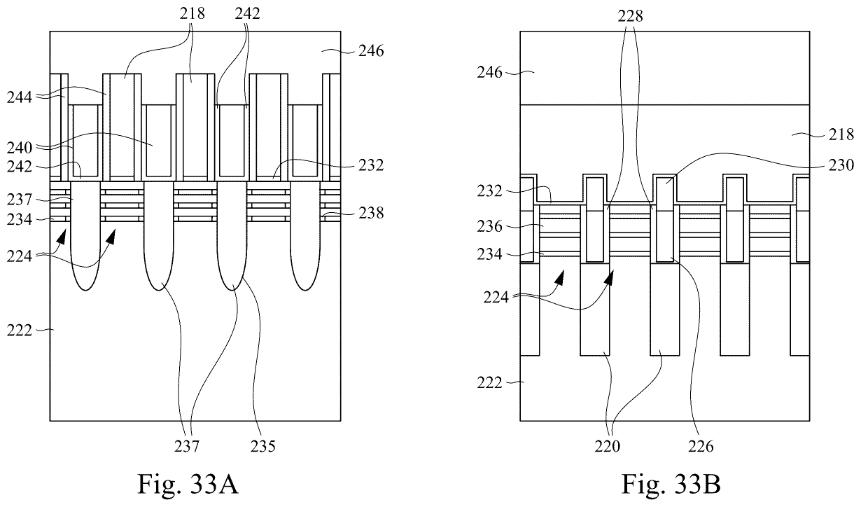

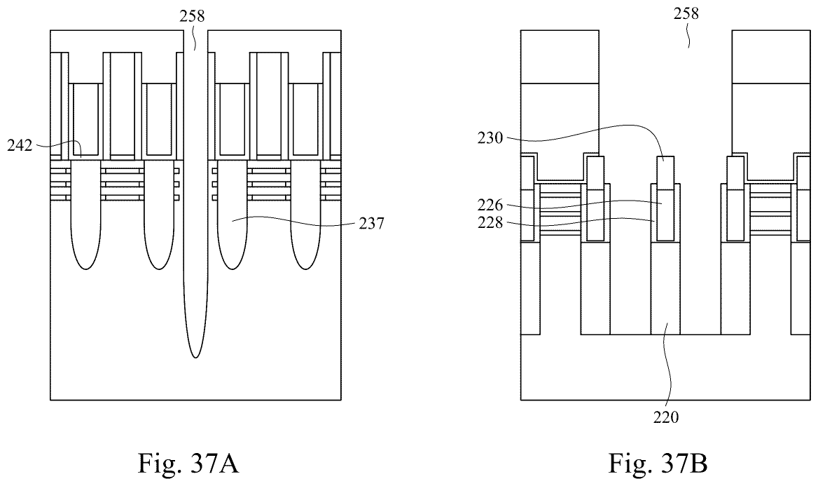

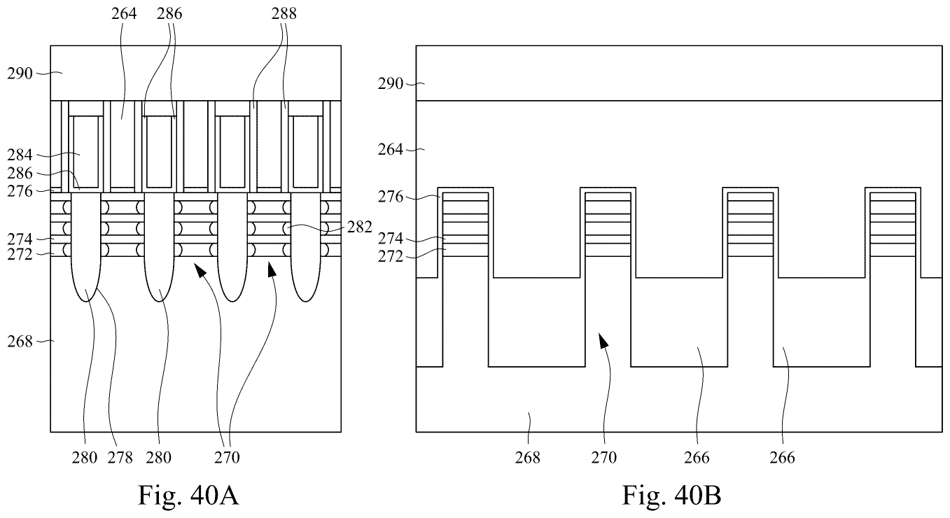

FIGS. 51A and 51B illustrate the structure following the formation of a conformal liner 354 in the opening 352 and deposition of a dielectric fill 356 over the liner 354. The conformal dielectric liner and the dielectric fill can include or be formed of any material or combination of materials and be formed by any process or combination of processes useful for respectively forming a conformal dielectric liner or a dielectric fill, such as any material, process, or combination thereof respectively described herein in connection with a conformal dielectric liner and a dielectric fill. FIGS. 52A and 52B illustrate the structure following planarization of the structure shown in FIGS. 51A and 51B, respectively, using a planarization process, such as a CMP process.

In embodiments of the present disclosure, openings are formed in structures of semiconductor devices without damaging or otherwise exposing structures such as source/drain structures, ILDs, hard mask layers over ILDs, metal gates, and sacrificial gates proximal the openings. The openings can have a high aspect ratio by minimizing head loss of etchants. The openings can be formed deep into a substrate below source/drain regions and STI regions to address current leakage. It will be understood that not all advantages have been necessarily discussed herein, no particular advantage is required for all embodiments or examples, and other embodiments or examples may offer different advantages.

According to an embodiment of the disclosure, a method of manufacturing a semiconductor device includes performing an etching process on a structure. The structure includes a substrate, STI regions disposed on the substrate, a plurality of fins spaced apart over the substrate and protruding from the STI regions. The plurality of fins extend in a first direction and include channel regions and recesses on opposite sides of the channel regions. A plurality of metal gates are disposed over the substrate and the STI regions. The plurality of metal gates extend in a second direction crossing the first direction and contact the channel regions. Source/drain structures are disposed in the recesses. The etching process includes extending an opening through a metal gate of the plurality of metal gates by removing a section of the metal gate extending in the second direction, extending the opening through a fin of the plurality of fins by removing a section of the fin extending in the first direction, extending the opening through an STI region of the STI regions by removing a portion of the STI region, and extending the opening into the substrate by removing a portion of the substrate. The opening extends to a depth in the substrate below the STI regions and the source/drain structures. One or more of the following conditions are met during the etching process: an etching pressure when extending the opening through the metal gate is lower than an etching pressure when extending the opening through the fin, the etching pressure when extending the opening through the fin is lower than an etching pressure when extending the opening through the STI region, the etching pressure when extending the opening through the STI region is lower than an etching pressure when extending the opening into the substrate, an etching temperature when extending the opening through the metal gate is higher than an etching temperature when extending the opening through the fin, the etching temperature when extending the opening through the fin is higher than an etching temperature when extending the opening through the STI region, the etching temperature when extending the opening through the STI region is higher than an etching temperature when extending the opening into the substrate, an etching selectivity of silicon over one or more silicon dioxide and silicon nitride is lower when extending the opening through the metal gate than when extending the opening through the fin, an etching selectivity of silicon over one or more silicon dioxide and silicon nitride is lower when extending the opening through the fin than when extending the opening through the STI region, an etching selectivity of silicon over one or more silicon dioxide and silicon nitride is lower when extending the opening through the STI region than when extending the opening into the substrate, and an etching pressure during one or more of extending the opening through the metal gate, extending the opening through the fin, extending the opening through the STI region, and extending the opening the into substrate is less than 50 mTorr. In an embodiment, removing the section of the fin forms the opening between a pair of source/drain structures of the source/drain structures and does not expose the pair of the source/drain structures along the first direction. In an embodiment, before the etching process, the structure further includes a hard mask layer isolating the section of the metal gate from a remainder of the metal gate along the second direction. In an embodiment, extending the opening by removing the section of the metal gate does not expose the remainder of the metal gate along the second direction. In an embodiment, before the etching process, the structure further includes a section of a semiconductor layer over the section of the metal gate and a remainder of the semiconductor layer over the remainder of the metal gate, and the section of the semiconductor layer is isolated from the remainder of the semiconductor layer by the hard mask layer. In an embodiment, the etching process further includes removing the section of the semiconductor layer without exposing the remainder of the semiconductor layer along the second direction. In an embodiment, the etching temperature when extending the opening through the metal gate is higher than the etching temperature when extending the opening through the fin. In an embodiment, the etching temperature when extending the opening through the STI region is higher than an etching temperature when extending the opening into the substrate. In an embodiment, the etching pressure when extending the opening through the metal gate is lower than the etching pressure when extending the opening through the fin. In an embodiment, the etching pressure when extending the opening through the STI region is lower than the etching pressure when extending the opening into the substrate.

According to another embodiment, a method of manufacturing a semiconductor device includes performing an etching process on a structure of the semiconductor device. The structure of the semiconductor device includes a substrate, a fin disposed across the substrate in a first direction and including a channel region. An STI region is disposed about the fin with the fin protruding from the STI region. A gate structure extends along a second direction crossing the first direction. The gate structure covers the channel region. Source/drain structures are formed on opposite sides of the gate structure at the channel region. The etching process includes extending an opening through the gate structure by removing a section of the gate structure extending in the second direction, extending the opening through the fin by removing a section of the fin extending in the first direction between the source/drain structures without exposing the source/drain structures, extending the opening through the STI region by removing a portion of the STI region, and extending the opening into the substrate by removing a portion of the substrate. The opening extends to a depth in the substrate below the STI region and the source/drain structures. One or more of the following conditions are met during the etching process: an etching pressure when extending the opening through the gate structure is lower than an etching pressure when extending the opening by removing the section of the stack, the etching pressure when extending the opening by removing the section of the stack is lower than an etching pressure when extending the opening through the STI region, the etching pressure when extending the opening through the STI region is lower than an etching pressure when extending the opening into the substrate, an etching temperature when extending the opening through the gate structure is higher than an etching temperature when extending the opening by removing the section of the stack, the etching temperature when extending the opening by removing the section of the stack is higher than an etching temperature when extending the opening through the STI region, and the etching temperature when extending the opening through the STI region is higher than an etching temperature when extending the opening into the substrate. In an embodiment, the structure further comprises a hard mask layer isolating the section of the gate structure from a remainder of the gate structure along the second direction. In an embodiment, removing the section of the gate structure does not expose the remainder of the gate structure along the second direction. In an embodiment, the etching pressure when extending the opening through the gate structure is lower than the etching pressure when extending the opening by removing the section of the stack. In an embodiment, the etching pressure when extending the opening through the gate structure is lower than the etching pressure when extending the opening by removing the section of the stack. In an embodiment, the etching temperature when extending the opening through the STI region is higher than the etching temperature when extending the opening into the substrate.

In another embodiment, a method of manufacturing a semiconductor device includes performing an etching process on a structure of the semiconductor device. The structure includes a substrate, a plurality of stacks including layers of semiconductor material formed over the substrate. The stacks extend along a first direction and including channel regions. A plurality of gate structures are formed over the substrate and extending along a second direction crossing the first direction, the gate structures covering the channel regions. Source/drain structures are formed on opposite sides of the channel regions along the first direction. A plurality of STI regions are disposed about the plurality of stacks. The etching process includes extending an opening through a gate structure of the plurality of gate structures by removing a section of the gate structure extending in the second direction, extending the opening by removing a section of a stack of the plurality of stacks between a pair of source/drain structures of the source/drain structures without exposing the pair of source/drain structures along the first direction, extending the opening through an STI region of the plurality of STI regions by removing a portion of the STI region, and extending the opening into the substrate by removing a portion of the substrate. The opening extends to a depth in the substrate below the plurality STI regions and the source/drain structures. One or more of the following conditions are met during the etching process: an etching pressure when extending the opening through the gate structure is lower than an etching pressure when extending the opening by removing the section of the stack, the etching pressure when extending the opening by removing the section of the stack is lower than an etching pressure when extending the opening through the STI region, the etching pressure when extending the opening through the STI region is lower than an etching pressure when extending the opening into the substrate, an etching temperature when extending the opening through the gate structure is higher than an etching temperature when extending the opening by removing the section of the stack, the etching temperature when extending the opening by removing the section of the stack is higher than an etching temperature when extending the opening through the STI region, the etching temperature when extending the opening through the STI region is higher than an etching temperature when extending the opening into the substrate, an etching selectivity of silicon over one or more silicon dioxide and silicon nitride is lower when extending the opening through the gate structure than when extending the opening by removing the section of the stack, an etching selectivity of silicon over one or more silicon dioxide and silicon nitride is lower when extending the opening by removing a section of the stack than when extending the opening through the STI region, an etching selectivity of silicon over one or more silicon dioxide and silicon nitride is lower when extending the opening through the STI region than when extending the opening into the substrate, and an etching pressure during one or more of extending the opening through the gate structure, extending the opening by removing the section of the stack, extending the opening through the STI region, and extending the opening the into substrate is less than 50 mTorr. In an embodiment, the structure further comprises a hard mask layer isolating the section of the gate structure from a remainder of the gate structure along the second direction. In an embodiment, removing the section of the gate structure does not expose the remainder of the gate structure along the second direction. In an embodiment, the etching pressure when extending the opening through the gate structure is lower than the etching pressure when extending the opening by removing the section of the stack.

In another embodiment, a semiconductor device includes a substrate and a plurality of STI regions disposed on the substrate. The device further includes a plurality of fins spaced apart over the substrate and protruding from the plurality of STI regions. The plurality of fins extend in a first direction and include channel regions and recesses on opposite sides of the channel regions. The device further includes a plurality of metal gates disposed over the substrate and the STI regions. The plurality of metal gates extend in a second direction and contact the channel regions of the plurality of fins. The device further includes source/drain structures disposed in the recesses. The device includes an opening filled with a dielectric material. The opening extends into the substrate to a depth below the STI regions and the source/drain structures. The opening divides a fin of the plurality of fins between a pair of source/drain structures of the source/drain structures along the first direction, the opening divides a metal gate of the plurality of metal gates along the second direction. A width of the opening decreases from a level at tops of the plurality of fins to a level at bottoms of the plurality of STI regions when viewed at a cross-section taken along the second direction. In an embodiment, the dielectric material does not contact the pair of the source/drain structures along the first direction. In an embodiment, the dielectric material does not contact the metal gate along the second direction. In an embodiment, the semiconductor device further includes ILD layers disposed over the source/drain structures, and the dielectric material does not contact the ILD layers disposed over the pair of the source/drain structures on opposite sides of the opening along the first direction. In an embodiment, the semiconductor device further includes first hard mask layers disposed over the ILD layers, and the dielectric material does not contact the first hard mask layers formed on the ILD layers disposed over the pair of the source/drain structures. In an embodiment, the semiconductor device further includes a semiconductor layer formed over the plurality of metal gates and about the ILD layers and the first hard mask layers. In an embodiment, the semiconductor device further includes gate cut structures spacing the opening from the semiconductor layer and the metal gate along the second direction. In an embodiment the semiconductor device further includes a second hard mask layer lining the gate cut structures. In an embodiment, the opening includes a plurality of trenches through an STI region of the STI regions and the substrate, and the plurality of trenches are spaced apart along the second direction. In an embodiment, the width of the opening gradually and continuously decreases from the level at the tops of the plurality of fins to the level at the bottoms of the plurality of STI regions.

In another embodiment, a semiconductor device includes a substrate and a FET device disposed on the substrate. The FET device includes a fin disposed across the substrate in a first direction. The fin includes a channel region. The FET device further includes an STI region disposed about the fin with the fin protruding from the STI region. The FET device further includes a gate structure extending along a second direction crossing the first direction. The gate structure covers the channel region. The FET device further includes source/drain structures formed on opposite sides of the gate structure at the channel region. The FET device further includes an opening filled with a dielectric material and extending into the substrate to a depth below the source/drain structures and below the STI region. The opening divides the fin along the first direction and divides the gate structure along the second direction. A width of the opening decreases from a level at a top of the fin to a level at a bottom of the STI region when viewed at a cross-section taken along the second direction. In an embodiment, the gate structure includes a dielectric structure or a metal gate. In an embodiment, the dielectric material does not contact the source/drain structures along the first direction. In an embodiment, the semiconductor device further includes ILD layers formed over the source/drain structures, and the dielectric material does not contact the ILD layers along the first direction. In an embodiment, the semiconductor device further includes a semiconductor layer formed over the gate structure, and the dielectric material does not contact the semiconductor layer along the second direction. In an embodiment, the width of the opening gradually and continuously decreases from the level at the top of the fin to the level at the bottom of the STI region.

In another embodiment, a semiconductor device includes a substrate and adjacent field-effect transistors (FET) devices on the substrate. The adjacent FET devices each include a stack including layers of a semiconductor material, such that the stack extends along a first direction and includes a channel region. The adjacent FET devices each further include a metal gate extending along a second direction crossing the first direction, such that the metal gate covers the channel region. The adjacent FET devices each further include source/drain epitaxial structures formed on opposite sides of the gate at the channel region. The adjacent FET devices each further include STI regions disposed about the stack. The semiconductor device further includes an opening filled with a dielectric material. The opening is formed between the adjacent FET devices. The opening extends into the substrate to a depth below the source/drain epitaxial structures and the STI regions. A width of the opening decreases from a level at tops of the stacks of the adjacent FET devices to a level at bottoms of the STI regions when viewed at a cross-section taken along the second direction. In an embodiment, the dielectric material does not contact the metal gate of both the adjacent FET devices along the second direction. In an embodiment, the semiconductor device further includes a hard mask layer between the opening and the metal gate of both the adjacent FET devices along the second direction. In an embodiment, the semiconductor device further includes an ILD layer formed over the source/drain structures, such that the dielectric material does not contact the ILD layer along the first direction. In an embodiment, the width of the opening gradually and continuously decreases from the level at the tops of the stacks to the level at the bottoms of the STI regions

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device comprising:
performing an etching process on a structure including:
a substrate,
shallow trench isolation (STI) regions disposed on the substrate,
a plurality of fins spaced apart over the substrate and protruding from the STI regions, the plurality of fins extending in a first direction and including channel regions and recesses on opposite sides of the channel regions,
a plurality of metal gates disposed over the substrate and the STI regions, the plurality of metal gates extending in a second direction crossing the first direction and contacting the channel regions, and
source/drain structures disposed in the recesses,
the etching process comprising:
extending an opening through a metal gate of the plurality of metal gates by removing a section of the metal gate extending in the second direction,
extending the opening through a fin of the plurality of fins by removing a section of the fin extending in the first direction,
extending the opening through an STI region of the STI regions by removing a portion of the STI region, and
extending the opening into the substrate by removing a portion of the substrate, the opening extending to a depth in the substrate below the STI regions and the source/drain structures,
wherein one or more of the following conditions are met during the etching process:
an etching pressure when extending the opening through the metal gate is lower than an etching pressure when extending the opening through the fin,
an etching pressure when extending the opening through the fin is lower than an etching pressure when extending the opening through the STI region,
an etching pressure when extending the opening through the STI region is lower than an etching pressure when extending the opening into the substrate,
an etching temperature when extending the opening through the metal gate is higher than an etching temperature when extending the opening through the fin,
an etching temperature when extending the opening through the fin is higher than an etching temperature when extending the opening through the STI region,
an etching temperature when extending the opening through the STI region is higher than an etching temperature when extending the opening into the substrate,
an etching selectivity of silicon over one or more silicon dioxide and silicon nitride is lower when extending the opening through the metal gate than when extending the opening through the fin,
an etching selectivity of silicon over one or more silicon dioxide and silicon nitride is lower when extending the opening through the fin than when extending the opening through the STI region,
an etching selectivity of silicon over one or more silicon dioxide and silicon nitride is lower when extending the opening through the STI region than when extending the opening into the substrate, and
an etching pressure during one or more of extending the opening through the metal gate, extending the opening through the fin, extending the opening through the STI region, and extending the opening the into substrate is less than 50 mTorr.

2. The method of claim 1, wherein removing the section of the fin forms the opening between a pair of source/drain structures of the source/drain structures and does not expose the pair of the source/drain structures along the first direction.

3. The method of claim 1, wherein, before the etching process, the structure further comprises a hard mask layer isolating the section of the metal gate from a remainder of the metal gate along the second direction.

4. The method of claim 3, wherein extending the opening by removing the section of the metal gate does not expose the remainder of the metal gate along the second direction.

5. The method of claim 3, wherein, before the etching process, the structure further comprises a section of a semiconductor layer over the section of the metal gate and a remainder of the semiconductor layer over the remainder of the metal gate, the section of the semiconductor layer being isolated from the remainder of the semiconductor layer by the hard mask layer.

6. The method of claim 5, wherein the etching process further comprises removing the section of the semiconductor layer without exposing the remainder of the semiconductor layer along the second direction.

7. The method of claim 1, wherein the etching temperature when extending the opening through the metal gate is higher than the etching temperature when extending the opening through the fin.

8. The method of claim 7, wherein an etching temperature when extending the opening through the STI region is higher than an etching temperature when extending the opening into the substrate.

9. The method of claim 1, wherein the etching pressure when extending the opening through the metal gate is lower than the etching pressure when extending the opening through the fin.

10. The method of claim 9, wherein the etching pressure when extending the opening through the STI region is lower than the etching pressure when extending the opening into the substrate.

11. A method of manufacturing a semiconductor device comprising:
performing an etching process on a structure of the semiconductor device, the structure including:
a substrate,
a plurality of stacks including layers of semiconductor material formed over the substrate, the stacks extending along a first direction and comprising channel regions,
a plurality of gate structures formed over the substrate and extending along a second direction crossing the first direction, the gate structures covering the channel regions,
source/drain structures formed on opposite sides of the channel regions along the first direction, and
a plurality of shallow trench isolation (STI) regions disposed about the plurality of stacks,
the etching process comprising:
extending an opening through a gate structure of the plurality of gate structures by removing a section of the gate structure extending in the second direction,
extending the opening by removing a section of a stack of the plurality of stacks between a pair of source/drain structures of the source/drain structures without exposing the pair of source/drain structures along the first direction,
extending the opening through an STI region of the plurality of STI regions by removing a portion of the STI region, and
extending the opening into the substrate by removing a portion of the substrate, the opening extending to a depth in the substrate below the plurality STI regions and the source/drain structures,
wherein one or more of the following conditions are met during the etching process:
an etching pressure when extending the opening through the gate structure is lower than an etching pressure when extending the opening by removing the section of the stack,
an etching pressure when extending the opening by removing the section of the stack is lower than an etching pressure when extending the opening through the STI region,
an etching pressure when extending the opening through the STI region is lower than an etching pressure when extending the opening into the substrate,
an etching temperature when extending the opening through the metal gate is higher than an etching temperature when extending the opening by removing the section of the stack,
an etching temperature when extending the opening by removing the section of the stack is higher than an etching temperature when extending the opening through the STI region,
an etching temperature when extending the opening through the STI region is higher than an etching temperature when extending the opening into the substrate,
an etching selectivity of silicon over one or more silicon dioxide and silicon nitride is lower when extending the opening through the gate structure than when extending the opening by removing the section of the stack,
an etching selectivity of silicon over one or more silicon dioxide and silicon nitride is lower when extending the opening by removing a section of the stack than when extending the opening through the STI region,
an etching selectivity of silicon over one or more silicon dioxide and silicon nitride is lower when extending the opening through the STI region than when extending the opening into the substrate, and
an etching pressure during one or more of extending the opening through the gate structure, extending the opening by removing the section of the stack, extending the opening through the STI region, and extending the opening the into substrate is less than 50 mTorr.

12. The method of claim 11, wherein the structure further comprises a hard mask layer isolating the section of the gate structure from a remainder of the gate structure along the second direction.

13. The method of claim 11, wherein removing the section of the gate structure does not expose the remainder of the gate structure along the second direction.

14. The method of claim 11, wherein the etching pressure when extending the opening through the gate structure is lower than the etching pressure when extending the opening by removing the section of the stack.

15. A semiconductor device comprising:
a substrate;
a plurality of shallow trench isolation (STI) regions disposed on the substrate,
a plurality of fins spaced apart over the substrate and protruding from the plurality of STI regions, the plurality of fins extending in a first direction and including channel regions and recesses on opposite sides of the channel regions;
a plurality of metal gates disposed over the substrate and the STI regions, the plurality of metal gates extending in a second direction and contacting the channel regions of the plurality of fins;
source/drain structures disposed in the recesses; and
an opening filled with a dielectric material, the opening extending into the substrate to a depth below the STI regions and the source/drain structures, the opening dividing a fin of the plurality of fins between a pair of source/drain structures of the source/drain structures along the first direction, the opening dividing a metal gate of the plurality of metal gates along the second direction, a width of the opening decreases from a level at tops of the plurality of fins to a level at bottoms of the plurality of STI regions when viewed at a cross-section taken along the second direction.

16. The semiconductor device of claim 15, wherein the dielectric material does not contact the pair of the source/drain structures along the first direction.

17. The semiconductor device of claim 15, wherein the dielectric material does not contact the metal gate along the second direction.

18. The semiconductor device of claim 15, further comprising interlayer dielectric (ILD) layers disposed over the source/drain structures, wherein the dielectric material does not contact the ILD layers disposed over the pair of the source/drain structures on opposite sides of the opening along the first direction.

19. The semiconductor device of claim 18, further comprising first hard mask layers disposed over the ILD layers, wherein the dielectric material does not contact the first hard mask layers formed on the ILD layers disposed over the pair of the source/drain structures.

20. The semiconductor device of claim 15, wherein the width of the opening gradually and continuously decreases from the level at the tops of the plurality of fins to the level at the bottoms of the plurality of STI regions.
